(19) United States
(12) Patent Application Publication
(10) Pub. No.: US 2026/0229879 A1
(43) Pub. Date: Aug. 6, 2026

(54) SYSTEM AND METHOD FOR PERFORMING FAULT MANAGEMENT IN ELECTRIC DISTRIBUTION NETWORKS

(71) Applicant: KING FAHD UNIVERSITY OF PETROLEUM AND MINERALS, Dhahran (SA)

(72) Inventors: Md SHAFIULLAH, Dhahran (SA); Md Nazrul Islam SIDDIQUE, Canberra (AU)

(73) Assignee: KING FAHD UNIVERSITY OF PETROLEUM AND MINERALS, Dhahran (SA)

(21) Appl. No.: 19/044,210

(22) Filed: Feb. 3, 2025

(51) Int. Cl. H02H 7/26; G01R 31/08

(52) U.S. Cl. CPC H02H 7/262; G01R 31/086

(57) ABSTRACT

A system for performing fault management in an electric distribution network includes: fault indicators (FIs) arranged at locations within the electric distribution network to detect faults within the electric distribution network and provide information on the detected faults, and remote-controlled sectionalizing switches (RCSs) and manual sectionalizing switches (MSs) arranged at the locations within the electric distribution network to isolate faulty parts from the electric distribution network to ensure power supply to unfaulty parts. The placement of the FIs, the RCSs, and the MSs are determined by solving an objective function, such that a sum of an equipment factor associated with the FIs, RCSs, and MSs, and an outage factor associated with service interruptions of the electric distribution network, to be reduced. The objective function includes a first term representing an outage factor calculated based on malfunction probability of the FIs, the RCSs, and the MSs.

### STATEMENT REGARDING PRIOR DISCLOSURE BY THE INVENTORS

Aspects of this technology are described in an article by Md Shafiullah and Md Nazrul Islam Siddique, “Fault Management Devices Placement in Electric Distribution Networks under Malfunction,” submitted to IEEE Transactions on Power Delivery on Jun. 20, 2024, and an article by Md Nazrul Islam Siddique, Md Juel Rana, Md Shafiullah, Saad Mekhilef, and Hemanshu Pota, “Automating distribution networks: Backtracking search algorithm for efficient and cost-effective fault management,” Expert Systems with Applications, Volume 247, Issue C, published on Aug. 1, 2024. The publications are herein incorporated by reference in their entirety.

### BACKGROUND

### Technical Field

The present disclosure is directed to electrical distribution network management systems, and particularly to systems and methods for performing fault management in electric distribution networks.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

Power outages in electric power system (EPS) networks can have significant repercussions for customers connected to distribution grids, resulting in outages for residential areas, businesses, and critical infrastructure. These outages can lead to various adverse effects, such as disrupting business operations, which in turn causes financial losses and reduced productivity. Public safety can also be at risk, as essential services, including emergency services and hospitals, rely on electricity supplied through distribution networks (DNS). Additionally, transportation and communication systems may experience disruptions, reducing efficiency and increasing operational expenses. Therefore, it is essential for utility providers to improve reliability and resilience of electrical distribution networks. By doing so, utilities can minimize a duration and a frequency of the outages, which in turn mitigates negative effects on the customers.

Most power outages are caused by faults in the electrical distribution networks. Prompt and accurate fault diagnosis is crucial, as it helps reduce downtime and speeds up a restoration of a power supply to affected customers by dispatching repair crews to fault sites. Real-time data collected from advanced measurement systems and fault diagnosis technologies allow the utilities to expedite restoration efforts, thus reducing the duration of the outages. Improved fault management strategies can enhance customer satisfaction, reduce costs associated with the outages, and minimize an impact on communities.

Several devices are commonly used in the EPS networks to assist with the fault diagnosis and management, including fault indicators (FIs) and sectionalizing switches (SSs). The FIs detect the faults and provide current information to operators, while the SSs isolate a faulty portion of the electrical distribution networks, ensuring the power supply to unaffected sections. However, installing such devices at every node in the electrical distribution networks is impractical due to high costs, complexity, and space limitations in densely populated areas. As a result, the FIs and the SSs are typically placed at strategic points in the electrical distribution networks, which necessitates solving optimization problems to determine a most effective placement.

An optimal placement of the FIs and the SSs has been a subject of extensive research, with several solution strategies proposed to determine suitable locations for these devices. These solutions can be broadly categorized into classical and heuristic methods. Among heuristic solutions, methods like ant colony optimization have been used to select optimal locations for the SSs, while techniques such as simulated annealing, differential search algorithms, and immune algorithms have been employed to minimize customer interruption costs by placing an optimal number of the SSs. Additionally, classical optimization approaches, including decomposition methods and mixed-integer linear programming (MILP), have also been utilized. For example, a multistage MILP-based approach was proposed to address budget limitations faced by investors.

In smart grids, the FIs have also been placed using evolutionary computing techniques. Other optimization methods, such as genetic algorithms, particle swarm optimization (PSO), and the MILP, have been explored for FI placement. However, most studies on the FI placement have not considered the impact of SS placement on the FIs, even though the SSs can significantly influence FI placement strategies. Some studies have treated the SS and FI placements separately, solving for SS locations first and then independently determining FI locations. Only a few studies have addressed simultaneous placement of the FIs and the SSs, incorporating fault isolation and management in a single optimization problem using the MILP. Despite these efforts, a critical issue such as, device malfunctions has often been overlooked. The device malfunctions can have serious implications for electric utilities, as malfunctioning of the SS or the FI can prolong the outages and reduce effectiveness of fault management.

A limited number of studies have accounted for malfunction probability of the devices in their optimization formulations. Addressing the device malfunctions adds complexity to a formulation and increases a computational burden, which can challenge traditional optimization tools that may become trapped in a local optima. To address these challenges, meta-heuristic algorithms have emerged as potential alternatives. However, the effectiveness of the meta-heuristic algorithms for placing the FIs and the SSs in the eletrical distribution networks has been rarely investigated.

In one conventional approach, an optimization method for placement of the SSs in the electric distribution networks based on Pareto front is described (See: A. C. Gomes, R. P. S. Le\tilde{ }ao, B. de Athayde Prata, F. L. Tofoli, R. F. Sampaio, and G. C. Barroso, “Optimal placement of manual and remote controlled switches based on the Pareto front,” International Journal of Electrical Power & Energy Systems, vol. 147, p. 108894, 202, incorporated herein by reference in its entirety). The method aims to balance multiple objectives such as minimizing equipment and outage costs. However, the described method is unable to consider malfunction of switches, potentially overlooking the impact of device failures on system reliability. Additionally, a reliance on traditional optimization techniques limits flexibility in adapting to dynamic network conditions.

In another conventional approach, the MILP based approach for the optimal placement of the SSs and tie lines in the electric distribution networks with complex topologies is described (See: M. Jooshaki, S. Karimi-Arpanahi, M. Lehtonen, R. J. Millar, and M. Fotuhi-Firuzabad, “An MILP model for optimal placement of sectionalizing switches and tie lines in distribution networks with complex topologies,” IEEE Transactions on Smart Grid, vol. 12, no. 6, pp. 4740-4751, 2021, incorporated herein by reference in its entirety). This model aims to improve network reliability and reduce the outage costs by optimizing switch placements. However, a limitation of this approach is its dependence on the MILP, which requires specific problem formatting and often relies on third-party solvers, potentially making it less adaptable to real-time or the dynamic network conditions. Additionally, the model does not account for switch malfunctions, which could affect its effectiveness in practical scenarios.

In yet another conventional approach, an optimization model for the placement of the FIs and the SSs in the electric distribution networks is described to enhance fault detection and reduce outage times (See: B. Li, J. Wei, Y. Liang, and B. Chen, “Optimal placement of fault indicator and sectionalizing switch in distribution networks,” IEEE Access, vol. 8, pp. 17 619-17 631, 2020, incorporated herein by reference in its entirety). This model focuses on minimizing equipment cost and the outage cost to improve the resilience of the network. However, the model does not consider the device malfunctions, which can impact accuracy and the reliability of a solution. Additionally, the model may require significant computational resources, which could limit its application in larger or more complex distribution networks.

Further, in another conventional approach, a method for simultaneous placement of the FIs and the SSs in the electric distribution networks to improve the fault management and the reliability is described (See: A. Safdarian, M. Farajollahi, and M. Fotuhi-Firuzabad, “Impacts of remote control switch malfunction on distribution system reliability,” IEEE Transactions on Power Systems, vol. 32, no. 2, pp. 1572-1573, 2016, incorporated herein by reference in its entirety). The described method optimizes the placement to minimize both the equipment cost and the outage cost, making it effective for cost reduction. However, the method does not consider the malfunction probabilities of the FIs and the SSs, which can affect fault tolerance of the system.

In yet another conventional approach, a model for the optimal placement of the SSs in the electric distribution networks, taking into account a probability of the switch malfunction is described (See: M. Farajollahi, M. Fotuhi-Firuzabad, and A. Safdarian, “Optimal placement of sectionalizing switch considering switch malfunction probability,” IEEE Transactions on Smart Grid, vol. 10, no. 1, pp. 403-413, 2017, incorporated herein by reference in its entirety). This approach is beneficial for enhancing the system reliability by considering realistic device performance. However, the approach focuses only on SS malfunctions and does not include other devices like the FIs, which potentially limits an applicability of the model in the electric distribution networks with diverse equipment.

In another conventional approach, a high-accuracy MILP model for optimal switch placement in the electric distribution network is described (See: A. Shahbazian, A. Fereidunian, and S. D. Manshadi, “Optimal switch placement in distribution systems: A high-accuracy MILP formulation,” IEEE Transactions on Smart Grid, vol. 11, no. 6, pp. 5009-5018, 2020, incorporated herein by reference in its entirety). MILP formulation provides precise solutions but relies heavily on the third-party solvers and specific data formatting, which can limit the flexibility and accessibility for broader implementation. Additionally, computational intensity of the MILP may pose challenges for large-scale systems, impacting the efficiency in practical applications.

In yet another conventional approach, a method for the optimal placement of remote-controlled switches in the electric distribution networks is described (See: J. Forcan and M. Forcan, “Optimal placement of remote-controlled switches in distribution networks considering load forecasting,” Sustainable Energy, Grids and Networks, vol. 30, p. 100600, 2022, incorporated herein by reference in its entirety) that incorporates load forecasting to enhance the network resilience and operational efficiency. While this method considers future load variations, it lacks the flexibility in addressing equipment malfunction probabilities, potentially limiting its effectiveness in real-world applications where switch failures may impact the reliability. Additionally, the reliance on accurate load forecasting models can introduce uncertainty if predictions do not align with actual demand trends.

In another conventional approach, a value-based mixed-integer non-linear programming (MINLP) model for the optimal placement of fuses and the switches in active distribution networks is described (See: N. Gholizadeh, S. H. Hosseinian, M. Abedi, H. Nafisi, and P. Siano, “Optimal placement of fuses and switches in active distribution networks using value-based MINLP,” Reliability Engineering & System Safety, vol. 217, p. 108075, 2022, incorporated herein by reference in its entirety) that aims to balance the reliability and the cost-effectiveness. However, the approach primarily focuses on minimizing the outage cost and the equipment cost while overlooking the impact of the device malfunctions. The reliance on the MINLP models also introduces high computational complexity, which may hinder scalability and real-time application in the large-scale networks.

Further, Patent Publication CN105186471A utilizes the FIs and the SSs to detect and isolate the faults, aiming to improve a response time and reduce the outage durations. However, this reference does not address the mulfunction probabilities of both the FIs and the SSs, which can result in increased outage durations and reduced network reliability due to delayed fault isolation and restoration.

Patent Publication CA2222674C describes a system for detecting and isolating the faults in the electrical distribution networks. However, the existing system fails to address the issue of the device malfunctions, such as the SS or the FI failure, in a fault management process.

Each of the aforementioned references suffers from one or more drawbacks hindering their adoption. For example, existing references fail to incorporate the malfunction probabilities of the FIs and the SSs, which is essential for a realistic and robust placement strategy. Additionally, the existing references often treat the FI and the SS placement as separate problem or fail to account for dependence of these devices, leading to suboptimal solutions. Furthermore, classical optimization tools can be computationally intensive and are prone to getting trapped in the local optima, making them less suitable for complex formulations that include the malfunction probabilities.

Accordingly, it is one object of the present disclosure to provide methods and systems for improving the fault management in the electrical power distribution networks by optimizing the placement of the FIs and the SSs, while accounting for potential device malfunctions. The proposed system integrates advanced meta-heuristic algorithms to determine the optimal placement of the FIs and the SSs, reducing the outage duration and the costs associated with service interruptions. By considering a likelihood of the FI and the SS failures, the disclosure aims to enhance the network reliability and the resilience, enabling faster fault detection, the isolation and the restoration for the affected customers, ultimately leading to more efficient and dependable power distribution.

### SUMMARY

In an exemplary embodiment, a system for performing fault management in an electric distribution network is disclosed. The system includes a plurality of fault indicators (FIs). The system further includes a plurality of one type of SS-remote-controlled sectionalizing switches (RCSs). The system further includes a plurality of other type of SS-manual sectionalizing switches (MSs) arranged in the electric distribution network. The plurality of FIs are configured to detect faults within the electric distribution network and provide information on the detected faults. The plurality of RCSs and the plurality of MSs are configured to isolate faulty parts from the electric distribution network to ensure power supply to unfaulty parts. The plurality of FIs, the plurality of RCSs, and the plurality of MSs are arranged at locations within the electric distribution network that are determined by solving an objective function, such that a sum of (1) an equipment factor associated with the plurality of FIs, the plurality of RCSs, and the plurality of MSs, and (2) an outage factor associated with service interruptions of the electric distribution network, to be minimized. The objective function includes a first term representing an outage factor calculated based on malfunction probability of the plurality of FIs, the plurality of RCSs, and the plurality of MSs.

In another exemplary embodiment, a method for performing fault management in an electric distribution network is disclosed. The method includes detecting faults within the electric distribution network and providing information on the detected faults, using a plurality of fault indicators (FIs) arranged in the electric distribution network. The method further includes isolating faulty parts from the electric distribution network and ensuring power supply to unfaulty parts, using a plurality of remote-controlled sectionalizing switches (RCSs) and a plurality of manual sectionalizing switches (MSs) arranged in the electric distribution network, wherein the plurality of FIs, the plurality of RCSs, and the plurality of MSs are arranged at locations within the electric distribution network that are determined by solving an objective function, such that a sum of (1) an equipment factor associated with the plurality of FIs, the plurality of RCSs, and the plurality of MSs, and (2) an outage factor associated with service interruptions of the electric distribution network, to be minimized. The objective function includes a first term representing an outage factor calculated based on malfunction probability of the plurality of FIs, the plurality of RCSs, and the plurality of MSs.

The foregoing general description of the illustrative embodiments and the following detailed description thereof are merely exemplary aspects of the teachings of this disclosure, and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1A illustrates a setup of an electric distribution network, according to certain embodiments.

FIG. 1B illustrates a block diagram of a system for performing fault management in the electric distribution network, according to certain embodiments.

FIG. 1C illustrates a feeder to present a modelling process, according to certain embodiments.

FIG. 2 illustrates a single-line diagram of a Roy Billington Test System (RBTS-Bus 4), according to certain embodiments.

FIG. 3 illustrates a graphical representation of multiple runs of a Backtracking Search Algorithm (BSA), according to certain embodiments.

FIG. 4A illustrates a graphical representation of manual sectionalizing switch (MS) placement with respect to malfunction probability, according to certain embodiments.

FIG. 4B illustrates a graphical representation of remote controlled sectionalizing switch (RCS) isolation capability with respect to the malfunction probability, according to certain embodiments.

FIG. 4C illustrates a graphical representation of RCS remote controllability malfunction probability, according to certain embodiments.

FIG. 4D illustrates a graphical representation of fault indicator (FI) placement with respect to the malfunction probability, according to certain embodiments.

FIG. 5 illustrates a graph representing a relationship between total costs and malfunction probabilities, according to certain embodiments.

FIG. 6 illustrates a flowchart of a method for performing the fault management in the electric distribution network, according to certain embodiments.

FIG. 7 is an illustration of a non-limiting example of details of computing hardware used in the computing system, according to certain embodiments.

FIG. 8 is an exemplary schematic diagram of a data processing system used within the computing system, according to certain embodiments.

FIG. 9 is an exemplary schematic diagram of a processor used with the computing system, according to certain embodiments.

FIG. 10 is an illustration of a non-limiting example of distributed components which may share processing with the controller, according to certain embodiments.

### DETAILED DESCRIPTION

In the drawings, like reference numerals designate identical or corresponding parts throughout the several views. Further, as used herein, the words “a,” “an” and the like generally carry a meaning of “one or more,” unless stated otherwise.

Furthermore, the terms “approximately,” “approximate,” “about,” and similar terms generally refer to ranges that include the identified value within a margin of 20%, 10%, or preferably 5%, and any values therebetween.

Aspects of this disclosure are directed to a system and a method for enhancing fault management in electric distribution networks by optimizing a placement of fault indicators (FIs) and sectionalizing switches (SSs) while accounting for device malfunction probabilities. Power outages may severely impact customers, leading to financial losses, decreased productivity, and potential risks to public safety. To mitigate these impacts, it is crucial to reduce outage durations through efficient fault detection and isolation. Modern fault management strategies require computational intelligence to accurately locate faults and isolate faulty sections, thereby minimizing the outage durations. However, deploying the FIs and the SSs at every node in the electric distribution networks is impractical due to cost, space, and complexity constraints. In addition, the FIs and the SSs are susceptible to malfunctions, which compromise reliability in maintaining service continuity.

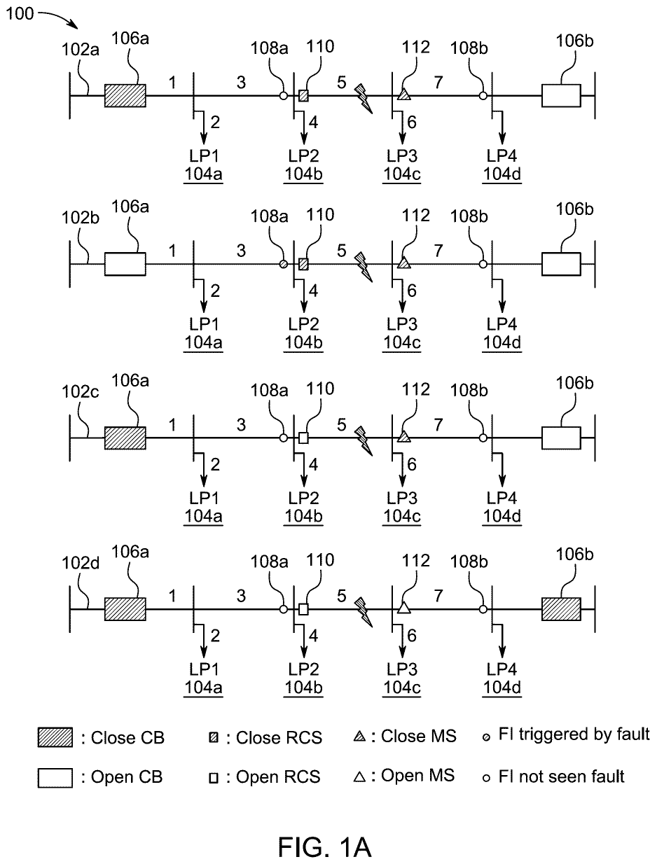

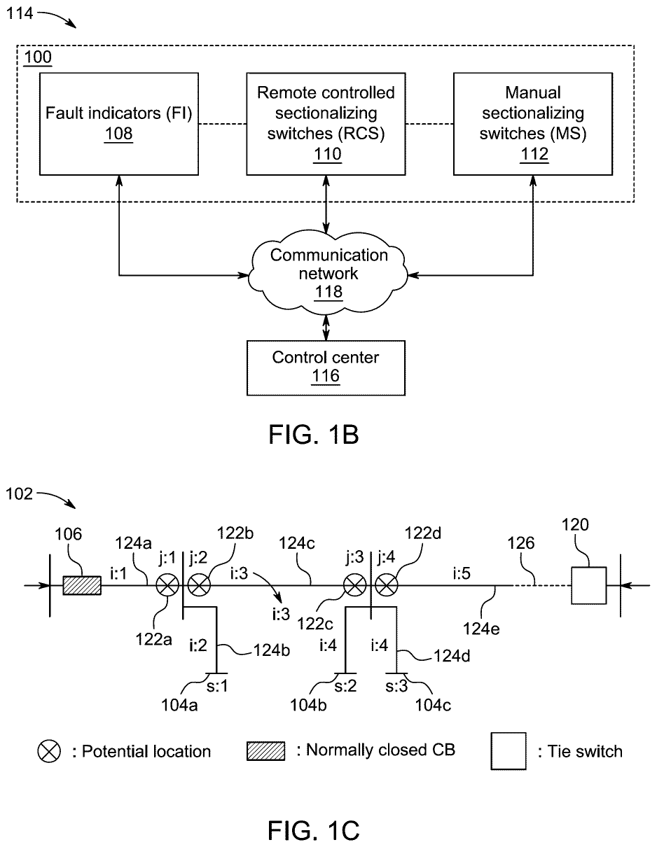

The present disclosure provides a system and method for performing fault management in an electric distribution network including FIs and SSs strategically placed at critical nodes determined through solving an optimization problem, aiming to balance device installation costs with a need to minimize service interruptions. A backtracking search algorithm (BSA) such as, a population based meta-heuristic method can be used to identify optimal device locations while considering an impact of potential malfunctions. By incorporating the device malfunction probabilities, the present disclosure demonstrates a more realistic approach to the fault management, revealing potential increases in total cost if device failures are overlooked. FIG. 1A illustrates a setup of an electric distribution network 100 (hereinafter referred to as the network 100), according to certain embodiments. The setup of the network 100 may be designed to deliver electricity from power sources to customers. In an exemplary embodiment, the customers may be, but not limited to, residential customers, commercial customers, industrial customers, and so forth. Embodiments of the present disclosure are intended to include or otherwise cover any type of the customers.

In the setup of the network 100, one or more components may be positioned along corresponding feeders 102a-102d (hereinafter collectively referred to as the feeders 102 and individually referred to as the feeder 102) of the network 100 to monitor and control a distribution of the electricity. In an embodiment, the components may be placed along the feeders 102 for restoring power supply quickly in case of any faults (hereinafter collectively referred to as the faults and individually referred to as the fault) that occur in the network 100. Restoring the power supply may involve steps of identifying a location of the fault, isolating faulty parts (hereinafter collectively referred to as the faulty parts and individually referred to as the faulty part) and reinstating the power to affected customers.

In an embodiment, each feeder 102 in the network 100 may be a primary line that delivers the power from substations to corresponding load points (LPs) 104a-104d (e.g., LP1, LP2, LP3 and LP4) (hereinafter collectively referred to as the LPs 104 and the individually referred to as the LP 104) and branches out to supply the electricity to different parts in the network 100. As used herein, the term “LPs 104” may represent areas or group of the customers connected to the network 100 for receiving the electricity.

Further, the components may be, but not limited to, circuit breakers (CBs) 106a-106b (hereinafter collectively referred to as the CBs 106 and individually referred to as the CB 106) on each feeder 102, fault indicators (FIs) 108a-108b (hereinafter collectively referred to as the FIs 108 and individually referred to as the FI 108) on each feeder 102, remote-controlled sectionalizing switches (RCSs) 110 (hereinafter collectively referred to as the RCSs 110 and individually referred to as the RCS 110) on each feeder 102 and manual sectionalizing switches (MSs) 112 (hereinafter collectively referred to as the MSs 112 and individually referred to as the MS 112) on each feeder 102.

The CB 106 may be represented by a rectangular box, that may control a flow of the power to various parts of the network 100. Under normal operating conditions, the CB 106 may remain closed (represented by a solid rectangular box in FIG. 1A), allowing the electricity to flow through the parts of the network 100. In an event of the faults, the CB 106 opens (represented by an empty rectangular box in FIG. 1A) to disconnect an affected part of the network 100, thereby preventing the faults from propagating and protecting downstream infrastructure.

Further, the FIs 108 may be represented by circles, to detect the faults, within specific parts of the network 100. In an exemplary embodiment, the faults may be, but not limited to, short-circuit faults, earth faults, overload faults, transient faults, and the like. Embodiments of the present invention are intended to include or otherwise cover any type of the faults. When the fault occurs, the FIs 108 may send signals representing real-time information to operators. In an exemplary embodiment, the signals may indicate the location of the fault. This real-time information may enable the operators to identify and isolate the faulty parts, thereby minimizing an impact on the customers. In an aspect, the FI 108 that is represented by a dark circle (i.e., FI 108 triggered by the fault), indicates that the fault may be detected by the FI 108 in a monitored part of the network 100. In such aspect, when the FI 108 is triggered, the FI 108 sends the signal indicating a presence of the fault in the monitored part of the network 100. In another aspect, the FI 108 that is represented by an empty circle (i.e., FI 108 not seen fault), indicates that no fault is detected by the FI 108 in the monitored part of the network 100. In other words, the monitored part of the network 100 is working normally.

The RCS 110 may be represented by a square box and enable the operators to remotely isolate the faulty parts of the network 100. By remotely opening the RCS 110 (represented by an empty square box as shown in FIG. 1A), the faulty part may be quickly disconnected from the feeder 102 without a need for manual intervention, thereby reducing an outage duration. However, under the normal conditions, the RCS 110 may remain closed (represented by a solid square box as shown in FIG. 1A) to allow the electricity to flow through the parts of the network 100.

The MS 112 may be represented by a triangle and operated manually to isolate the parts of the network 100 during the faults. While the MS 112 requires a physical access to operate, the MS 112 provides an essential backup mechanism for fault isolation, especially in scenarios where the RCS 110 in unavailable or fails to operate. Similar to the RCS 110, under the normal conditions, the MS 112 may remain closed (represented by a solid triangle as shown in FIG. 1A) to allow the electricity to flow through the parts of the network 100. However, in case of the faults, the MS 112 may be opened (represented by an empty triangle as shown in FIG. 1A) manually to isolate the faulty part from the network 100.

In an exemplary embodiment, when the fault occurs in a part 5 of the corresponding feeder 102, then the FI 108 provides the location of the fault zone to the operators, which includes the part 5, part 6 and part 7 of the corresponding feeder 102. This alerts the operators to the affected parts of the feeder 102 so that the operators take appropriate actions. Due to the fault in the part 5, downstream load points such as, the LP3 104c and the LP4 104d that are connected to the part 5 lose the power temporarily. As used herein, the term “downstream load points” refer to points that lie beyond the fault or interruption when there is the fault in a particular part of the network 100. Based on the received location of the fault, the operators may operate the RCS 110 to isolate the load points LP1 104a and LP2 104b from the faulted part. By using the RCS 110, the power may be quickly restored to the load points LP1 104a and LP2 104b, minimizing the outages for the customers of the load points LP1 104a and LP2 104b.

For other load points such as, the LP4 104d, which is controlled by the MS 112, requires the physical access for power restoration. Therefore, the LP4 104d remains interrupted until field crews locate and isolate the fault. This may lead to variable restoration times depending on how quickly the field crews respond to the fault. Further, in an aspect, the load point LP3 104c may not be restored using the RCS 110 or the MS 112 and may take longer time to repair.

In an aspect, if the FI 108 fails to operate, the field crews need to manually patrol all lines to locate the fault. This leads to longer interruption period, as manually identifying the location of the fault takes more time. Further, in an aspect, if the RCS 110 is unable to operate remotely, then the customers at the LP1 104a and the LP2 104b experience the outage until the fault is located and restored manually. In another aspect, if the RCS 110 is unable to open manually, then the customers may continue experiencing the outage until the faulty part is repaired. In an aspect, if the network 100 detects any malfunction in the MS 112, then the customers on the LP4 104d cannot be restored until the fault is repaired.

Therefore, an optimal placement of the FIs 108, the RCSs 110 and the MSs 112 on the network 100 is essential as the optimal placement of devices such as, the FIs 108, the RCSs 110 and the MSs 112 reduces cost associated with service interruption.

FIG. 1B illustrates a block diagram of a system 114 for performing fault management in the network 100, according to certain embodiments. In an embodiment, the system 114 may be configured to determine optimal locations for a placement of the devices such as, the FIs 108, the RCSs 110 and the MSs 112 on the network 100. In such embodiment, the system 114 may be configured to determine the optimal locations for the placement of the FIs 108, the RCSs 110 and the MSs 112 within the network 100 to improve the fault management and reduce outage durations. Further, the system 114 may also be configured to identify and detect the faults within the network 100 to pinpoint the locations of the corresponding faults accurately. The system 114 may also be configured to automatically isolate the faulty parts from the network 100, ensuring that the impact of the fault is minimized. In an embodiment, the system 114 may also be configured to restore the power by rerouting the electricity through unaffected parts of the network 100. In another embodiment, the system 114 may be configured to restore the power by closing sectionalizing switches (SSs) once the fault is cleared, reducing downtime for the customers. In an aspect, the SSs may be the RCSs 110 and the MSs 112.

According to embodiments of the present disclosure, the system 114 may include the FIs 108, the RCSs 110, the MSs 112, a control center 116 and a communication network 118. The FIs 108 may be placed at various locations along lines of the feeder 102 (as shown in FIG. 1A) of the network 100, to continuously monitor the network 100 to detect the faults within the network 100. In an embodiment, the FIs 108 may provide information on the detected faults to the control center 116 through the communication network 118. In another embodiment, the FIs 108 may directly communicate with the RCSs 110 for providing the information on the detected faults to the RCSs 110. In an exemplary embodiment, the FIs 108 may be equipped with sensors that may monitor values of electrical data in the network 100. The electrical data may be, but not limited to, current levels, voltage levels, and so forth. Embodiments of the present invention are intended to include or otherwise cover any type of the electrical data. Further, the FIs 108 may compare the values of the electrical data with predefined baseline values for determining if the values of the monitored electrical data deviates from the predefined baseline values. In an embodiment, the FIs 108 may be configured to transmit the signal indicating the presence of the fault to the control center 116 through the communication network 118. In another embodiment, the FIs 108 may be configured to transmit the signal indicating the presence of the fault directly to the RCSs 110.

In an embodiment, the RCSs 110 may be configured to receive the information on the detected faults from the FIs 108. In another embodiment, the RCSs 110 may be configured to receive the information on the detected faults from the control center 116 through the communication network 118. The RCSs 110 may be placed at the various locations along the lines of the feeder 102 of the network 100, to isolate the faulty parts from the network 100 to ensure the power supply to unfaulty parts. The RCSs 110 may be operated remotely from the control center 116 that may allow a quick switching without a need of a technician on-site. Also, the RCSs 110 may offer faster response times for isolating the faulty parts from the network 100. In an exemplary embodiment, the RCSs 110 may be remotely operated from the control center 116 to open or close the RCSs 110, allowing isolation and restoration of specific parts of the network 100.

Further, the MSs 112 may also be placed at the various locations along the lines of the feeder 102 of the network 100, to control the flow of the electricity in the network 100. The MSs 112 may be configured to enable the operators to isolate the faulty parts from the network 100 to ensure the power supply to the unfaulty parts. In an embodiment, the MSs 112 may be operated by field personnel.

The control center 116 may be a main operational hub for managing and monitoring the network 100. In an embodiment, the control center 116 may be configured to analyze data from the FIs 108 and the RCSs 110 to detect the faults, locate the faults and determine necessary actions to isolate and resolve issues. In an embodiment, the control center 116 may send commands to the RCSs 110 to open or close switches as needed to isolate or restore the power to a specific part in the network 100. The control center 116 may be configured to continuously monitor a status of the network 100 through the communication network 118 by receiving the data from the devices such as, the FIs 108 and the RCSs 110.

The communication network 118 may enable data exchange between the control center 116 and the devices such as, the FIs 108 and the RCSs 110. The communication network 118 may be, but not limited to, a fiber optic communication network, a radio frequency (RF) communication network, a cellular network, a wireless mesh network, a satellite communication network, and so forth. Embodiments of the present invention are intended to include or otherwise cover any type of the communication network 118 including known related art and/or later developed technologies.

In an embodiment, the various locations for the placement of the FIs 108, the RCSs 110 and the MSs 112 within the network 100 may be determined by formulating an optimization problem that considers cost-benefit analysis over a long term. The optimization problem may assume one or more conditions for determining the locations for the FIs 108, the RCSs 110 and MSs 112. A first condition may be assumed that the network 100 is structured as a radial network, a second condition may be assumed that the fault occurring in one feeder 102 does not impact neighboring feeders, a third condition may be assumed that each fault is repaired before any subsequent fault occurrences, a forth condition may be assumed that power system components are modeled with an average interruption rate independent of aging and a fifth condition may be assumed that the FIs 108 and the SSs such as, the RCSs 110 and the MSs 112 are placed on a main section of the feeder 102.

In an embodiment, the FIs 108, the RCSs 110, and MSs 112 may be represented by decision variables such as, X^{FI}_{f,j}, X^{RCS}_{f,j}, X^{MS}_{f,j}, respectively. In an exemplary embodiment, the X^{FI}_{f,j} indicates the placement of the FI 108 at a location j 122a-122d (hereinafter referred to as the location j 122) (as shown in FIG. 1C) on a feeder f 102. Similarly, the X^{RCS}_{f,j} indicates the placement of the RCS 110 at the location j 122 on the feeder f 102. Further, the X^{MS}_{f,j} indicates the placement of the MS 112 at the location j 122 on the feeder f 102. As discussed earlier that the FIs 108 provide the information on fault currents, while the MSs 112 serve to isolate the faulty parts. Therefore, it is possible to install both the FIs 108 and the MSs 112 at a location. However, the placement of the RCSs 110 is exclusive and cannot coincide with either the MSs 112 or the FIs 108. In an aspect, one or more constraints may be defined below in equation (1) and equation (2) for determining the placement of the FIs 108, the RCSs 110 and the MSs 112 in the network 100.

$${X}_{f , j}^{M S} + {X}_{f , j}^{RCS} \leq 1 ; \qquad ( 1 )$$

$${X}_{f , j}^{FI} + {X}_{f , j}^{RCS} \leq 1 ; \qquad ( 2 )$$

where the equation (1) indicates that a total number of the RCSs 110 and the MSs 112 arranged at each location within the network 100 is not more than 1. This ensures that each potential location is able to accommodate only one type of switch installation such as, either the RCS 110 or the MS 112. In other words, the RCS 110 and the MS 112 cannot exist at the same location. The equation (2) indicates that a total number of the RCSs 110 and the FIs 108 arranged at each location within the network 100 is not more than 1, which prevents a co-location of the RCS 110, and the FIs 108.

Further, in an embodiment, the system 114 may be configured to determine the placement of the FIs 108, the RCSs 110, and the MSs 112 by solving an objective function. In an embodiment, the objective function may be defined as a sum of cost factors such as, an equipment factor (C^{eq}) and an outage factor (C^{out}) as shown below in an equation (3):

$$Minimize ( {C}^{e q} ) + ( {C}^{out} ) \qquad ( 3 )$$

The C^{eq} may be an equipment factor that is associated with the FIs 108, the RCSs 110 and the MSs 112 and the C^{out} may be an outage factor that is associated with service interruptions of the network 100, that needs to be minimized.

Further, the C^{eq} may include a sum of an installation factor and a maintenance factor. The installation factor may be an installation factor that is associated with the FIs 108, the RCSs 110 and the MSs 112. The installation factor is also associated with communication devices required by the FIs 108, and the RCSs 110. As used herein, the term “installation factor” may refer to an initial cost of deploying the FIs 108, the RCSs 110 and the MSs 112 at the various locations. Further, the maintenance factor may be a maintenance factor associated with FIs 108, the RCSs 110 and the MSs 112. The maintenance factor is calculated using a discount factor. The discount factor may be determined based on an investment factor and a time factor associated with the FIs 108, the RCSs 110 and the MSs 112. Also, as used herein, the term “maintenance factor” may refer to an ongoing cost of maintaining the FIs 108, the RCSs 110, and the MSs 112 over time. The C^{eq} may be expressed in equation (4) as below:

$${C}^{e q} = {\sum }_{f ∈ {N}_{f}} {\sum }_{j ∈ {N}_{j}} [ {X}_{f , j}^{R C S} {C}_{f , j}^{R C S} + {X}_{f , j}^{M S} {C}_{f , j}^{M S} + {X}_{f , j}^{FI} {C}_{f , j}^{FI} ] + {\sum }_{t ∈ {N}_{t}} {\sum }_{f ∈ {N}_{f}} {\sum }_{j ∈ {N}_{j}} \frac{1}{{( 1 + d )}^{t}} [ {X}_{f , j}^{R C S} M {C}_{f , j}^{R C S} + {X}_{f , j}^{M S} M {C}_{f , j}^{M S} + {X}_{f , j}^{FI} M {C}_{f , j}^{FI} ] \qquad ( 4 )$$

where

$${\sum }_{f ∈ {N}_{f}} {\sum }_{j ∈ {N}_{j}} [ {X}_{f , j}^{R C S} {C}_{f , j}^{R C S} + {X}_{f , j}^{M S} {C}_{f , j}^{M S} + {X}_{f , j}^{FI} {C}_{f , j}^{FI} ]$$

represents the installation cost (factor) and

$${\sum }_{t ∈ {N}_{t}} {\sum }_{f ∈ {N}_{f}} {\sum }_{j ∈ {N}_{j}} \frac{1}{{( 1 + d )}^{t}} [ {X}_{f , j}^{R C S} M {C}_{f , j}^{R C S} + {X}_{f , j}^{M S} M {C}_{f , j}^{M S} + {X}_{f , j}^{FI} M {C}_{f , j}^{FI} ]$$

represents the maintenance cost (factor) and d indicates annual discount rate. Also, t∈Nₜ indicates an index and set of years, f∈N_{f} represents the index and set of feeders 102, j∈Nⱼ denotes the index and set of potential equipment (device) locations,

$${C}_{f , j}^{R C S}$$

denotes a capital cost or the RCS 110 in the feeder f 102 at the location j 122

$${C}_{f , j}^{FI}$$

denotes the capital cost of the MS 112 in the feeder f 102 at the location j 122 and

$${C}_{f , j}^{M S}$$

denotes the capital cost or the FI 108 in the feeder f 102 at the location j 122.

$${MC}_{f , j}^{R C S}$$

denotes a maintenance cost of the RCS 110 in the feeder f 102 at the location j 122,

$${MC}_{f , j}^{MS}$$

denotes the maintenance cost of the RCS 110 in the feeder f 102 at the location j 122,

$${MC}_{f , j}^{FI}$$

denotes the maintenance cost of the FI 108 in the feeder f 102 at the location j 122. Further, d is the discount factor applied to future maintenance costs, representing a present value of future maintenance expenditures.

Further, the C^{out} may be calculated below in equation (5) as:

$${C}^{out} = {\sum }_{t ∈ {N}_{t}} {\sum }_{f ∈ {N}_{f}} {\sum }_{i ∈ {N}_{i}} {\sum }_{s ∈ {N}_{s}} {\sum }_{k ∈ {N}_{k}} \frac{{( 1 + q )}^{t - 1}}{{( 1 + d )}^{t}} [ {γ}_{t , f , i} {Lo}_{t , f , s , k} {C}_{t , f , i , s , k}^{sum} ] \qquad ( 5 )$$

where i∈Nᵢ denotes the index and set of possible fault locations, s∈Nₛ denotes the index and set of load points 104 (as shown in FIG. 1A), k∈Nₖ denotes the index and set of customer types. Further, γ_{t,f,i} denotes a failure rate at a section i 124a-124e (hereinafter referred to as the section i 124) (as shown in FIG. 1C) of the feeder f 102 at the year t, Lo_{t,f,s,k} denotes an average load of the customers with the type k at load point s 104 in the feeder f 102 at the year

$${C}_{t , f , i , s , k}^{sum}$$

denotes a total outage cost incurred on the customers with the type k at the load point s 104 for the fault at the section i 124c and the feeder f 102 at the year t, d denotes an annual depreciation rate and q denotes a load growth.

The equation (5) contains parameters that may be determined based on the network 100 and

$${C}_{t , f , i , s , k}^{sum}$$

may be a parameter that depends on the placement of the FIs 108, the RCSs 110, and the MCs 112, how the placement of the FIs 108, the RCSs 110, and the MCs 112 affect fault isolation and customer interruptions. A process of calculating the

$${C}_{t , f , i , s , k}^{sum}$$

by considering malfunctions, a number of the FIs 108, the RCSs 110 and the MSs 112 and the placement of the FIs 108, the RCSs 110 and the MSs 112 is explained in detail in FIG. 1C.

Further, the objective function for determining the placement of the FIs 108, the RCSs 110, and the MSs 112 in the network 100 is solved by applying a population-based meta-heuristic algorithm. In a preferred embodiment, the population based meta-heuristic algorithm may be a backtracking search algorithm (BSA). The BSA may be selected due to success of the BSA in various engineering applications, such as, a time series forecasting, a dynamic economic dispatch, a real power generation optimization for hydrothermal plants, and an optimal placement of photovoltaic systems.

The BSA may include various steps such as, initialization, fitness evaluation, selection 1, mutation, crossover, selection 2, and termination criteria. The initialization involves a step of starting the BSA with a population of solutions. The fitness evaluation involves a step of assessing how well each solution performs based on a predefined objective. Further, the selection 1 involves a step of selecting individuals based on a fitness of the individuals for further reproduction. The mutation step involves introducing random changes to the selected individuals to explore a solution space. Further, the crossover involves a step of combining parts of two or more individuals to create new candidates. The selection 2 involves a step of selecting the candidates based on the fitness of an offspring. The termination criteria involve a step of stopping the BSA once certain conditions such as, reaching a maximum number of generations are met.

The BSA operates as a dual-population algorithm, utilizing both current and historical populations to generate new candidate solutions. A mutation strategy of the BSA is random, changes only one direction for each target individual. This characteristic distinguishes the BSA from other evolutionary algorithms that may prioritize better-fitted individuals more frequently, as the BSA introduces diversity by randomly selecting a direction of the mutation from the individuals in a previous generation.

Furthermore, the BSA employs a complex, non-uniform crossover strategy, allowing for a retention of a diverse population of randomly selected individuals, which aids in determining a search direction. Even in later generations, the BSA ensures diversity by adjusting both the search direction and a search magnitude, guided by a global search criterion and a local search criterion.

The BSA also incorporates a unique boundary control mechanism to ensure that the search remains within feasible solution spaces.

In an aspect, the BSA may be applied to solve the optimization problem associated with the placement of the FIs 108, the RCSs 110 and the MSs 112 in the network 100. The objective function of the optimization problem is represented in an equation (6) as defined below:

$${min}_{x \to } F = {C}^{eq} + {C}^{out} \qquad ( 6 )$$

where F represents the objective function and x^{→} represents a vector of the decision variables combining the X^{RCS}_{f,j}, X^{MS}_{f,j} and X^{FI}_{f,j}. In an aspect, the optimization is subject to equations constraints (1)-(2), (4)-(59), except (6).

FIG. 1C illustrates the feeder 102 to present a modelling process, according to certain embodiments. The feeder 102 may include the circuit breaker (CB) 106 that may be represented at a start of a line of the feeder 102. The CB 106 may be typically closed, allowing the current to flow through the line under the normal operating conditions. The CB 106 may be open to disconnect the feeder 102 in case of the faults or maintenance.

The feeder 102 also includes a tie-switch 120 that may be located at an end of the line, and may be typically open under the normal conditions. In an aspect, the tie-switch 120 may be closed to connect the feeder 102 to another feeder or provide an alternative path to balance load or restore the power during the outages. The feeder 102 also includes potential locations 122a-122d (hereinafter referred to as the locations 122) for installing the FIs 108 (as shown in FIG. 1A), the SSs (i.e., RCSs 110 (as shown in FIG. 1A), and the MSs 112 (as shown in FIG. 1A)). The locations 122 may be represented as j:1, j:2, j:3 and j:4. Further, the feeder 102 includes sections 124a-124e (hereinafter referred to as the sections 124) that may be represented as i:1, i:2, i:3, i:4 and i:5. The sections 124 represent distinct points where the power is distributed further. The feeder 102 also includes the load points 104a-104c (hereinafter referred to as the load points 104) that may be represented as s:1, s:2 and s:3. The load points 104 are the locations where the feeder 102 supplies the power directly to the customers. Further, a dashed line 126 that is extending from a right side toward the tie switch 120 represents a segment of the feeder 102 that may be connected to other feeders.

Further, FIG. 1C illustrates fault location and detection strategy within the network 100, where odd-numbered sections 124a, 124c and 124e (i.e. i:1, i:3 and i:5) represent primary branches, while even-numbered sections 124b and 124d (i.e. i:2, i:4) represent laterals (branches off the main feeder 102). When multiple laterals are connecting to the main feeder 102, then the multiple laterals are treated as a single section 124 and share a same even number. In an ideal scenario, devices such as the FIs 108 and the RCSs 110 can be installed at both ends of the main feeder 102. This setup helps improve the fault isolation and restoration by identifying the fault location quickly and accurately. In an exemplary scenario as shown in FIG. 1C, when the fault occurs (e.g., in a third section 124c (i.e., i: 3)), the FI 108 located at a first section 124a (i.e., j: 1) is activated, but the RCS 110 at the third section 124c (i.e., j: 3) remains inactive which indicates that the fault is in either a second section 124b (i.e., i: 2) or the third section 124c (i.e., i: 3). This helps the field crews to narrow down a fault zone, reducing an area that the field crews need to inspect. In an aspect, the fault zone may be calculated by evaluating whether each section 124 is within the fault zone or outside the fault zone by using below defined equations:

$${S}_{f , i , l} = {\sum }_{j = i}^{l - 1} {X}_{f , j}^{RCS} + {\sum }_{j = i}^{l - 1} {X}_{f , j}^{FI} ; ∀ i < l \qquad ( 7 )$$

$${S}_{f , i , l} = {\sum }_{j = l}^{i - 1} {X}_{f , j}^{RCS} + {\sum }_{j = l}^{i - 1} {X}_{f , j}^{FI} ; ∀ l < i \qquad ( 8 )$$

$$α - \frac{1}{β} {S}_{f , i , l} \leq {L}_{f , i , l} \leq 1 - \frac{1}{β} {S}_{f , i , l} + α \qquad ( 9 )$$

$$∀ f ∈ {N}_{f} , ∀ i ∈ {N}_{i} , ∀ l ∈ {N}_{l}$$

$$\begin{matrix}{L}_{f , i , l} = 1 ; & ∀ i = l\end{matrix} \qquad ( 10 )$$

where S_{f,i,1} indicates an integer variable indicating a number of the FIs 108 and the RCSs 110 between a faulty section i 124c and a section 1 in the feeder f 102, L_{f,i,l} indicates a binary variable indicating that the section 1 is involved in the fault zone for the fault at the location i 124c in the feeder f 102 without FI 108 malfunction, α and β indicate small and large auxiliary constants respectively, and 1∈Nₗ indicates the index and set of feeder 102 sections.

Equation (7) and equation (8) define a fault location indicator based on positions of the RCS 110 and FI 108 devices relative to the faulted section i 124c and other sections 124 in the feeder f 102. When there are FIs 108 or the RCSs 110 between the faulted section i 124c and an upstream and downstream non-faulted section 1, then the S_{f,i,l} does not take 0. The L_{f,i,l} is set equal to 0 according to an equation (9), indicating that the section 1 is outside the fault zone. On the other hand, if the S_{f,i,l} is 0, then the equation (9) forces L_{f,i,l} to take a value of 1, indicating that the section 1 is within the fault zone. Once the fault zone is identified, the field crews patrol suspected areas to confirm an exact fault location and the time it takes to locate the fault depends on a line length, field crew patrolling preparation time and patrolling speed for a specific section 1, and the locations of the FIs 108, the RCSs 110, and the MSs 112 within the network 100.

Further, the system 114 may be configured to calculate a fault locating time by using an equation (11) as defined below:

$${t}_{f , i}^{loc} = {\sum }_{l ∈ {N}_{l}} \frac{{len}_{f , l}}{{P}_{f , l}} {L}_{f , i , l} + {t}_{f}^{prep} ; ∀ f ∈ {N}_{f} , ∀ i ∈ {N}_{i} \qquad ( 11 )$$

where

$${t}_{f , i}^{l o c}$$

indicates the time needed for locating the fault at the location i 124c in the feeder f 102 without the malfunction, the len_{f,l} indicates a length of the section 1 in the feeder f 102, the P_{f,l} indicates a patrol speed of the field crews for the section 1 in the feeder f 102, and the

$${t}_{f}^{prep}$$

indicates a preparation time required for the field crews in the feeder f 102.

In the network 100, the customers may experience varying durations of power outages, influenced by the placement of the devices. For example, if the RCS 110 is positioned between the load point 104 and the fault, the customers in that segment may be promptly disconnected, resulting in only a brief disruption before the power is restored. Conversely, the customers who are not isolated from the fault needs to wait until the fault location is determined. After identifying the fault, the customers who can be isolated using the MSs 112 may have their power restored through appropriate switching actions. However, other customers who cannot be isolated from the faulted section 124c may wait for repair of the fault, leading to a prolonged outage. To assess the impact of the outages across different customer categories, the system 114 may be configured to calculate the outage costs for different customer categories according to the placement and a type of the SSs as defined in equations (12)-(16). In an aspect, the customers who can be restored via the RCSs 110 may be calculated using the equation (12) as defined below:

$${C}_{t , f , i , s , k} \geq {df}_{t , f , i , s , k} ( {t}_{f , i , s}^{RCS} ) ; \qquad ( 12 )$$

$$∀ t ∈ {N}_{t} , ∀ f ∈ {N}_{f} , ∀ i ∈ {N}_{i} , ∀ s ∈ {N}_{s} , ∀ k ∈ {N}_{k}$$

where the C_{t,f,i,s,k} indicates the outage cost incurred on the customers with the type k at the load point s 104 for the fault at the section i 124c and the feeder f 102 at the year t if all the SSs and the FIs 108 function properly, the df_{t,f,i,s,k} illustrates a customer damage function value for the customers with the type k at the load point s 104 for the fault at the location i 124c and the feeder f 102 at the year t, the t^{RCS}_{f,i,s} indicates a remote restoration time for the customers at the load point s 104 for the fault at the location i 124c in the feeder f 102.

In an aspect, the customers who can be isolated using the MSs 112 have their costs determined using the equation (13) and the equation (14) as defined below:

$${C}_{t , f , i , s , k} \geq {df}_{t , f , i , s , k} ( {t}_{f , i}^{loc} ) [ 1 - {\sum }_{j = i}^{2 s - 1} {X}_{f , j}^{R C S} ] ; \qquad ( 13 )$$

$$∀ t ∈ {N}_{t} , ∀ f ∈ {N}_{f} , ∀ i ∈ {N}_{i} , ∀ s < {N}_{s} , ∀ k ∈ {N}_{k}$$

$${C}_{t , f , i , s , k} \geq {df}_{t , f , i , s , k} ( {t}_{f , i}^{loc} ) [ 1 - {\sum }_{j = 2 s}^{i - 1} {X}_{f , j}^{RCS} ] ; \qquad ( 14 )$$

$$∀ t ∈ {N}_{t} , ∀ f ∈ {N}_{f} , ∀ i ∈ {N}_{i} , ∀ s < \frac{i}{2} , ∀ k ∈ {N}_{k}$$

Further, in an aspect, the customers who cannot be isolated using any SSs are subject to interruption until the faulted section 124c is repaired, and their outage cost is calculated using the equation (15) and the equation (16).

$${C}_{t , f , i , s , k} \geq {df}_{t , f , i , s , k} ( {t}_{f , i}^{loc} + {t}_{f , i}^{rep} ) [ 1 - {\sum }_{j = i}^{2 s - 1} ( {X}_{f , j}^{RCS} + {X}_{f , j}^{M S} ) ] ; \qquad ( 15 )$$

$$∀ t ∈ {N}_{t} , ∀ f ∈ {N}_{f} , ∀ i ∈ {N}_{i} , ∀ s < \frac{i}{2} , ∀ k ∈ {N}_{k}$$

$${C}_{t , f , i , s , k} \geq {df}_{t , f , i , s , k} ( {t}_{f , i}^{loc} + {t}_{f , i}^{rep} ) [ 1 - {\sum }_{j = 2 s}^{i - 1} ( {X}_{f , j}^{RCS} + {X}_{f , j}^{MS} ) ] ; \qquad ( 16 )$$

$$∀ t ∈ {N}_{t} , ∀ f ∈ {N}_{f} , ∀ i ∈ {N}_{i} , ∀ s < \frac{i}{2} , ∀ k ∈ {N}_{k}$$

where the t_{f,i}^{rep} indicates a repair time of the fault section i 124c in the feeder f 102.

The aforementioned formulations may be applied to the customers on the laterals and the feeders 102 equipped with distributed generators (DGs), except in cases where the DGs cannot operate in an isolated mode. In such cases, repair and restoration costs may be calculated according to the equations (15)-(17).

$${C}_{t , f , i , s , k} , \geq {df}_{t , f , i , s , k} , ( {t}_{f , i}^{loc} + {t}_{f , i}^{rep} ) ; \qquad ( 17 )$$

$$∀ t ∈ {N}_{t} , ∀ f ∈ {N}_{f} , ∀ i ∈ {N}_{i} , ∀ s < \frac{i}{2} , ∀ k ∈ {N}_{k}$$

The equations (12) to (17) assume that all SSs and the FIs 108 are working properly, and therefore provide an underestimation of the outage costs. In real-world scenarios, failures of these devices such as, the MSs 112, the RCSs 110, and the FIs 108 may significantly affect a duration of customers experience interruptions in a service. The failure of the MS 112 may be termed as MS 112 malfunction that may delay the isolation of the faults and therefore extend the outage durations for the customers. The system 114 may be configured to calculate the outage cost of the MS 112 malfunction along the feeder 102 using equations (18) to (23).

$${C}_{t , f , i , s , k}^{s - M S} = {\sum }_{{j}^{′} ∈ {N}_{j}} {X}_{f , {j}^{′}}^{M S} {C}_{t , f , i , s , k , {j}^{′}} \qquad ( 18 )$$

where the

$${C}_{t , f , i , s , k}^{s - M S}$$

indicates the outage cost incurred on the customers with the type k at the load point s 104 for the fault at the section i 124c and the feeder f 102 at the year t due to the MS 112 isolation malfunction. The

$${X}_{f , {j}^{′}}^{M S}$$

indicates the placement of the MS 112 at a location j′ (not shown) on the feeder f 102. The

$${C}_{t , f , i , s , k}^{s - M S}$$

indicates the outage cost incurred on the customers with the type k at the load point s 104 for the fault at the section i 124c and the feeder f 102 at the year t if the SS and the FI 108 in the location j′ malfunction.

The equation (18) calculates the outage cost for each customer by considering the MS 112 malfunctions. Specifically, if the MS 112 is located at the location j′, then the

$${X}_{f , {j}^{′}}^{M S}$$

is equal to 1, indicating that the outage cost due to the MS 112 malfunction at the location j′ is included in the C_{t,f,i,s,k,j}′. The outage cost associated with the MS 112 malfunction is computed in the equations (18) to (23) similarly to the previous equations (12)-(17) but with the MS 112 malfunction factored in. However, the X^{MS}_{f,j′} may be excluded from a second summation in the equations (22) and (23) to account for the MS 112 malfunction at the location j′, thus reflecting an increase in the outage duration for the affected customers.

$${C}_{t , f , i , s , k , {j}^{′}} \geq {df}_{t , f , i , s , k} ( {t}_{f , i , s}^{R C S} ) ; \qquad ( 19 )$$

$${C}_{t , f , i , s , k , {j}^{′}} \geq {df}_{t , f , i , s , k} ( {t}_{f , i}^{l o c} ) [ 1 - {\sum }_{j = i}^{2 s} {X}_{f , j}^{R C S} ] ; \qquad ( 20 )$$

$${C}_{t , f , i , s , k , {j}^{′}} \geq {df}_{t , f , i , s , k} ( {t}_{f , i}^{l o c} ) [ 1 - {\sum }_{j = 2 s}^{i - 1} {X}_{f , j}^{R C S} ] ; \qquad ( 21 )$$

$$\begin{matrix}{C}_{t , f , i , s , k , {j}^{′}} \geq {df}_{t , f , i , s , k} ( {t}_{f , i}^{l o c} + {t}_{f , i}^{rep} ) [ 1 - ( {\sum }_{j = i}^{2 s} {X}_{f , j}^{R C S} + {\sum }_{{j = i}_{j \neq {j}^{′}}}^{2 s - 1} {X}_{f , j}^{M S} ) ] ; & ( 22 )\end{matrix}$$

$${C}_{t , f , i , s , k , {j}^{′}} \geq {df}_{t , f , i , s , k} ( {t}_{f , i}^{l o c} + {t}_{f , i}^{rep} ) [ 1 - ( {\sum }_{j = 2 s}^{i - 1} {X}_{f , j}^{R C S} + {\sum }_{{j = 2 s}_{j \neq {j}^{′}}}^{i - 1} {X}_{f , j}^{M S} ) ] ; \qquad ( 23 )$$

Further, the outage cost due to RCS 110 malfunction involves two primary factors such as, a malfunction in isolation capacity and a communication failure to receive the signals. The impact of the malfunction in the isolation capacity on customer interruption cost may be defined in equations (24) to (29). The equation (24) represents a customer outage cost due to the malfunction in the isolation capacity of the RCS 110. In an aspect, if the RCS 110 fails to isolate the fault (i.e., separate the faulty section 124c from the rest of the network 100), then it is considered if the RCS 110 is non-functional at that specific location and corresponding costs are adjusted accordingly.

$${C}_{t , f , i , s , k}^{sI - RCS} = {\sum }_{{j}^{′} ∈ {N}_{j}} {X}_{f , {j}^{′}}^{R c s} {C}_{t , f , i , s , k , {j}^{′}} ; \qquad ( 24 )$$

where the

$${C}_{t , f , i , s , k}^{sI - RCS}$$

indicates the outage cost incurred on the customers with the type k at the load point s 104 for the fault at the section i 124c and the feeder f 102 at the year t due to the isolation capability malfunction in the RCS 110. The

$${X}_{f , {j}^{′}}^{R C S}$$

indicates the placement of the RCS 110 at the location j′ on the feeder f 102.

Further, equations (25) to (29) calculates the outage cost based on whether the fault can be isolated and how long the isolation may take including delays from the RCS 110 malfunction. In an aspect, if the RCS 110 cannot isolate the fault, then it is assumed that it does not exist at the location j′. Thus, a summation associated with the RCS 110 in the equations (26) to (29) may exclude the location j′.

$${C}_{t , f , i , s , k , {j}^{′}} \geq {df}_{t , f , i , s , k} ( {t}_{f , i , s}^{R C S} ) ; \qquad ( 25 )$$

$${C}_{t , f , i , s , k , {j}^{′}} \geq {df}_{t , f , i , s , k} ( {t}_{f , i}^{loc} ) [ 1 - {\sum }_{{j = i}_{j \neq {j}^{′}}}^{2 s - 1} {X}_{f , j}^{R C S} ] ; \qquad ( 26 )$$

$${C}_{t , f , i , s , k , {j}^{′}} \geq {df}_{t , f , i , s , k} ( {t}_{f , i}^{loc} ) [ 1 - {\sum }_{{j = 2 s}_{j \neq {j}^{′}}}^{i - 1} {X}_{f , j}^{R C S} ] ; \qquad ( 27 )$$

$${C}_{t , f , i , s , k , {j}^{′}} \geq {df}_{t , f , i , s , k} ( {t}_{f , i}^{loc} + {t}_{f , i}^{rep} ) [ 1 - ( {\sum }_{j = i}^{2 s - 1} {X}_{f , j}^{MS} + {\sum }_{{j = i}_{j \neq {j}^{′}}}^{2 s - 1} {X}_{f , j}^{R C S} ) ] ; \qquad ( 28 )$$

$${C}_{t , f , i , s , k , {j}^{′}} \geq {df}_{t , f , i , s , k} ( {t}_{f , i}^{loc} + {t}_{f , i}^{rep} ) [ 1 - ( {\sum }_{j = 2 s}^{i - 1} {X}_{f , j}^{M S} + {\sum }_{{j = 2 s}_{j \neq {j}^{′}}}^{i - 1} {X}_{f , j}^{R C S} ) ] ; \qquad ( 30 )$$

Further, in RCS 110 communication failures, the RCS 110 may not be able to remotely isolate the fault section 124c but can manually isolate the fault. Here, the system 114 may be configured to determine the outage cost associated with the RCS 110 communication failure of the customers by using equations (30) to (35).

$${C}_{t , f , i , s , k}^{s R - R C S} = {\sum }_{{j}^{′} ∈ {N}_{j}} {X}_{f , {j}^{′}}^{R C S} {C}_{t , f , i , s , k , {j}^{′}} ; \qquad ( 30 )$$

$${C}_{t , f , i , s , k , {j}^{′}} \geq {df}_{t , f , i , s , k} ( {t}_{f , i , s}^{R C S} ) \qquad ( 31 )$$

$${C}_{t , f , i , s , k , {j}^{′}} \geq {df}_{t , f , i , s , k} ( {t}_{f , i}^{l o c} ) [ 1 - {\sum }_{{j = i}_{j \neq {j}^{′}}}^{2 s - 1} {x}_{f , j}^{R C S} ] ; \qquad ( 32 )$$

$${C}_{t , f , i , s , k , {j}^{′}} \geq {df}_{t , f , i , s , k} ( {t}_{f , i}^{l o c} ) [ 1 - {\sum }_{{j = 2 s}_{j \neq {j}^{′}}}^{i - 1} {X}_{f , j}^{R C S} ] ; \qquad ( 33 )$$

$${C}_{t , f , i , s , k , {j}^{′}} \geq {df}_{t , f , i , s , k} ( {t}_{f , i}^{l o c} + {t}_{f , i}^{r e p} ) [ 1 - ( {\sum }_{j = i}^{2 s} {X}_{f , j}^{M S} + {X}_{f , j}^{R C S} ) ] ; \qquad ( 34 )$$

$${C}_{t , f , i , s , k , {j}^{′}} \geq {df}_{t , f , i , s , k} ( {t}_{f , i}^{l o c} + {t}_{f , i}^{r e p} ) [ 1 - ( {\sum }_{j = 2 s}^{i - 1} {X}_{f , j}^{M S} + {x}_{f , j}^{R c s} ) ] ; \qquad ( 35 )$$

where the

$${C}_{t , f , i , s , k}^{sR - RCS}$$

indicates the outage cost incurred on the customers with the type k at the load point s 104 for the fault at the section i 124c and the feeder f 102 at the year t due to RCS 110 remote communication failure.

Further, in case of FI 108 malfunction at a specific location (e.g., j′) on the feeder 102, then it is assumed the FI 108 is either non-functional at the specific location or not available at the specific location. The FI 108 malfunction at the specific location increases a search space for the field crews, resulting in a long time to locate the fault. The system 114 may be configured to calculate the fault zone and the fault location time by using below defined equations:

$${S}_{f , i , l}^{′} = {\sum }_{j = i}^{l - 1} {X}_{f , j}^{R C S} + {\sum }_{{j = l}_{j \neq {j}^{′}}}^{i - 1} {X}_{f , j}^{FI} ; ∀ i < 1 ; \qquad ( 36 )$$

$${S}_{f , i , l}^{′} = {\sum }_{j = l}^{i - 1} {X}_{f , j}^{R C S} + {\sum }_{{j = l}_{j \neq {j}^{′}}}^{i - 1} {X}_{f , j}^{FI} ; ∀ i < i ; \qquad ( 37 )$$

$$α - \frac{1}{β} {S}_{f , i , l}^{′} \leq {L}_{f , i , l}^{′} \leq 1 - \frac{1}{β} {S}_{f , i , l}^{′} + α ; \qquad ( 38 )$$

$${t}_{f , i}^{{loc}^{′}} = {\sum }_{l ∈ {N}_{l}} \frac{l e {n}_{f , l}}{{P}_{f , l}} {L}_{f , i , l}^{′} + {T}_{f}^{p r e p} ; \qquad ( 39 )$$

where the

$${S}_{f , i , l}^{′}$$

indicates the integer variable indicating the number of FIs 108 and the RCS 110 between the fault location i 124c and the section 1 in the feeder f 102 with the FI 108 malfunction, the

$${X}_{f , j}^{FI} ,$$

indicates the placement of the FI 108 at the location j′ on the feeder f 102. The

$${L}_{f , i , l}^{′}$$

indicates the binary variable indicating the section 1 is involved in the fault zone for the fault at the location i 124c in the feeder f 102 with the FI 108 malfunction, the len_{f,l} indicates a length of the section 1 in the feeder f 102, the P_{f,l} indicates the patrol speed of the field crews for the section 1 in the feeder f 102, the

$${t}_{f , i}^{{loc}^{′}}$$

indicates the time needed for locating the fault at the location i 124c in the feeder f 102 with the FI 108 malfunction.

Further, the system 114 may be configured to calculate the customer outage cost due to the FI 108 malfunction by using below defined equations (40) to (45).

$${C}_{t , f , i , s , k}^{s - FI} = {\sum }_{{j}^{′} ∈ {N}_{j}} {X}_{f , {j}^{′}}^{FI} {C}_{t , f , i , s , k , {j}^{′}} \qquad ( 40 )$$

$${C}_{t , f , i , s , k , {j}^{′}} \geq {df}_{t , f , i , s , k} ( {t}_{f , i , s}^{R C S} ) \qquad ( 41 )$$

$${C}_{t , f , i , s , k , {j}^{′}} \geq {df}_{t , f , i , s , k} ( {t}_{f , i}^{{loc}^{′}} ) [ 1 - {\sum }_{j = i}^{2 s - 1} {X}_{f , j}^{R C S} ] \qquad ( 42 )$$

$${C}_{t , f , i , s , k , {j}^{′}} \geq {df}_{t , f , i , s , k} ( {t}_{f , i}^{{loc}^{′}} ) [ 1 - {\sum }_{j = 2 s}^{i - 1} {X}_{f , j}^{R C S} ] \qquad ( 43 )$$

$${C}_{t , f , i , s , k , {j}^{′}} \geq {df}_{t , f , i , s , k} ( {t}_{f , i}^{{loc}^{′}} + {t}_{f , i}^{rep} ) [ 1 - {\sum }_{j = 1}^{2 s} ( {X}_{f , j}^{R C S} + {X}_{f , j}^{M S} ) ] ; \qquad ( 44 )$$

$${C}_{t , f , i , s , k , {j}^{′}} \geq {df}_{t , f , i , s , k} ( {t}_{f , i}^{{loc}^{′}} + {t}_{f , i}^{rep} ) [ 1 - {\sum }_{j = 2 s}^{i - 1} ( {X}_{f , j}^{R C S} + {X}_{f , j}^{M S} ) ] ; \qquad ( 45 )$$

where the

$${C}_{t , f , i , s , k}^{s - FI}$$

indicates the outage cost incurred on the customers with the type k at the load point s 104 for the fault at the section i 124c and the feeder f 102 at the year t due to FI 108 triggering malfunction.

Further, in an embodiment, the system 114 may be configured to calculate the customer outage costs, probabilities of the malfunctions and proper functioning of the devices such as, the RCSs 110, the MSs 112, and the FIs 108 within the network 100. MS 112 function and the MS 112 malfunction probability may be determined by using equations (46) to (49).

$${No}_{f}^{M S} = {\sum }_{j ∈ {N}_{j}} {X}_{f , j}^{M S} ; \qquad ( 46 )$$

The equation (46) calculates the No^{MS}_{f}, i.e., a total number of the MSs 112 installed along the feeder f 102 by summing the MSs 112 at each location j 122 within the feeder f 102 as the number of the MSs 112 allocated in the feeder f 102 affects a probability of different MS 112 states.

$$\frac{{No}_{f}^{M S} - u}{β} + α \leq {a}_{f , u}^{M s} \leq \frac{{No}_{f}^{M S}}{u} + α ∀ f ∈ {N}_{f} , ∀ u ∈ {N}_{u} \qquad ( 47 )$$

In the equation (47), a value of the

$${a}_{f , u}^{M S}$$

is set to 1 for u less than or equal to the Nous

$${No}_{f}^{M S} ,$$

where the

$${a}_{f , u}^{M S}$$

indicates the binary variable to include a change of the malfunction or the function probability by adding the u^{th} device in the feeder f 102, and the u∈Nᵤ indicates the index and set of SSs and FIs 108 number.

$${P}_{f}^{M S} = {\sum }_{u ∈ {N}_{u}} {λ}_{u}^{M S} {a}_{f , u}^{M S} ; \qquad ( 48 )$$

In equation (48), the

$${P}_{f}^{M S}$$

is the probability of all the MSs 112 in the feeder f 102 that are functioning properly. The

$${P}_{f}^{M S}$$

may be calculated by using the

$${a}_{f , u}^{M S}$$

values, where

$${λ}_{u}^{M S}$$

is a constant value representing a change in the

$${P}_{f}^{M S}$$

by adding the u^{th} MS 112.

$${P}_{f}^{s - MS} = {\sum }_{u ∈ {N}_{u}} {λ}_{u}^{s - MS} {a}_{f , u}^{MS} \qquad ( 49 )$$

where the

$${P}_{f}^{s - MS}$$

represents the malfunction probability of one MS 112 in the feeder 102. Only one MS 112 malfunction at a time in the feeder 102 is considered, with no simultaneous malfunctions factored in. Also, the constant value

$${λ}_{u}^{s - MS}$$

is used in the equation (49) to account for change in the

$${P}_{f}^{s - MS}$$

by adding the u^{th} MS 112.

Similarly, RCS 110 function and RCS 110 malfunction probability may be determined by using equations (50) to (54).

$${No}_{f}^{RCS} = {\sum }_{j ∈ {N}_{j}} {X}_{f , j}^{RCS} ; \qquad ( 50 )$$

The equation (50) calculates the

$${No}_{f}^{RCS}$$

i.e., a total number of the RCSs 110 installed along the feeder f 102 by summing the RCSs 110 at each location j 122 within the feeder f 102.

$$\frac{{No}_{f}^{RCS} - u}{β} + α \leq {a}_{f , u}^{RCS} \leq \frac{{No}_{f}^{RCS}}{u} + α ; ∀ f ∈ {N}_{f} , ∀ u ∈ {N}_{u} \qquad ( 51 )$$

In equation (51), the value of the

$${a}_{f , u}^{RCS}$$

is set to 1 for u less than or equal to the

$${No}_{f}^{RCS} .$$

### The

$${a}_{f , u}^{RCS}$$

indicates the binary variable to include a change of the malfunction or the function probability by adding the u^{th} device in the feeder f 102.

$${P}_{f}^{RCS} = {\sum }_{u ∈ {N}_{u}} {λ}_{u}^{RCS} {a}_{f , u}^{RCS} ; \qquad ( 52 )$$

The

$${P}_{f}^{RCS}$$

indicates the probability of working all RCSs 110 on the feeder f 102. The P^{RCS}_{f} may be calculated by using the

$${a}_{f , u}^{RCS}$$

values, where the

$${λ}_{u}^{RCS}$$

is a constant value representing a change in the P^{RCS}_{f} by adding the u^{th} RCS 110.

$${P}_{f}^{sI - RCS} = {\sum }_{u ∈ {N}_{u}} {λ}_{u}^{sI - RCS} {a}_{f , u}^{RCS} ; \qquad ( 53 )$$

where the

$${P}_{f}^{sI - RCS}$$

indicates the isolation capacity malfunction of the RCS 110 in the feeder f 102. The

$${λ}_{u}^{sI - RCS}$$

indicates a fixed value used to account for variations in the probabilities, which are determined by the

$${a}_{f , u}^{RCS} .$$

$${P}_{f}^{sR - RCS} = {\sum }_{u ∈ {N}_{u}} {λ}_{u}^{sR - RCS} {a}_{f , u}^{RCS} ; \qquad ( 54 )$$

where the

$${P}_{f}^{sR - RCS}$$

indicates the probability of the communication failure of the RCS 110 and

$${λ}_{u}^{sR - RCS}$$

indicates the fixed value used to account for variations in the probabilities, which are determined by the

$${a}_{f , u}^{RCS} .$$

Similarly, FI 108 function and FI 108 malfunction probability may be determined by using equations (55) to (58).

$${No}_{f}^{FI} = {\sum }_{j ∈ {N}_{j}} {X}_{f , j}^{FI} ; \qquad ( 55 )$$

The equation (55) calculates the

$${No}_{f}^{FI} ,$$

i.e., a total number of the FIs 108 installed along the feeder f 102 by summing the FIs 108 at each location j 122 within the feeder f 102.

$$\frac{{No}_{f}^{FI} - u}{β} + α \leq {a}_{f , u}^{FI} \leq \frac{N {o}_{f}^{FI}}{u} + α ; ∀ f ∈ {N}_{f} , ∀ u ∈ {N}_{u} \qquad ( 56 )$$

In the equation (56), the value of the

$${a}_{f , u}^{FI}$$

is set to 1 for u less than or equal to the

$${No}_{f}^{FI} .$$

### The

$${a}_{f , u}^{FI}$$

indicates the binary variable to include a change of the malfunction or the function probability by adding the u^{th} device in the feeder f 102.

$${P}_{f}^{FI} = {\sum }_{u ∈ {N}_{u}} {λ}_{u}^{FI} {a}_{f , u}^{FI} \qquad ( 57 )$$

where the

$${P}_{f}^{FI}$$

indicates the probability of functioning all FIs 108 on the feeder 102. The

$${P}_{f}^{FI}$$

may be calculated by using the

$${a}_{f , u}^{FI}$$

values, where

$${λ}_{u}^{FI}$$

is a constant value representing a change in the

$${P}_{f}^{FI}$$

by adding the u^{th} FT.

$${P}_{f}^{s - FI} = {\sum }_{u ∈ {N}_{u}} {λ}_{u}^{s - FI} {a}_{f , u}^{FI} ; \qquad ( 58 )$$

wher

$${P}_{f}^{s - FI}$$

indicates the malfunction probability of one FI 108 in the feeder 102. The constant value

$${λ}_{u}^{s - FI}$$

is used in the equation (58) to account for the change in the

$${P}_{f}^{s - FI}$$

by adding the u^{th} FI 108.

Further, the system 114 may be configured to calculate the total outage cost by using a weighted sum of different outage costs as defined below in equation (59).

$${C}_{t , f , i , s , k}^{sum} = {P}_{f}^{MS} {P}_{f}^{RCS} {P}_{f}^{FI} {C}_{t , f , i , s , k} + {P}_{f}^{s - MS} {P}_{f}^{RCS} {P}_{f}^{FI} {C}_{t , f , i , s , k}^{s - MS} + {P}_{f}^{MS} {P}_{f}^{sI - RCS} {P}_{f}^{FI} {C}_{t , f , i , s , k}^{sI - RCS} + {P}_{f}^{MS} {P}_{f}^{s R - RCS} {P}_{f}^{FI} {C}_{t , f , i , s , k}^{sR - RCS} + {P}_{f}^{s - FI} {P}_{f}^{RCS} {P}_{f}^{MS} {C}_{t , f , i , s , k}^{s - FI} ; \qquad ( 59 )$$

where the

$${C}_{t , f , i , s , k}^{sum}$$

represents the total outage cost incurred on the customers with the type k at the load point s 104 for the fault at the section i 124c and the feeder f 102 at the year t, the first term

$${P}_{f}^{MS} {P}_{f}^{RCS} {P}_{f}^{FI} {C}_{t , f , i , s , k}$$

indicates the outage factor calculated assuming that there is no malfunction in the FIs 108, the RCSs 110, and the MSs 112. Further, the second term

$${P}_{f}^{s - MS} {P}_{f}^{RCS} {P}_{f}^{FI} {C}_{t , f , i , s , k}^{s - M S}$$

indicates the outage factor calculated based on the malfunction probability of the MSs 112 where a status of the MSs 112 cannot be altered. The third term

$${P}_{f}^{M S} {P}_{f}^{sI - RCS} {P}_{f}^{FI} {C}_{t , f , i , s , k}^{sI - RCS}$$

indicates the outage factor calculated based on the malfunction probability of the isolation capability of the RCSs 110 where a status of the RCSs 110 cannot be altered. The fourth term

$${P}_{f}^{M S} {P}_{f}^{s R - R C S} {P}_{f}^{FI} {C}_{t , f , i , s , k}^{s R - R C S}$$

indicates the outage factor calculated based on the malfunction probability of the remote communication capability of the RCSs 110 where a status of the RCSs 110 can be altered manually but not remotely. The fifth term

$${P}_{f}^{s - FI} {P}_{f}^{R C S} {P}_{f}^{M S} {C}_{t , f , i , s , k}^{s - FI}$$

indicates the outage factor calculated based on the malfunction probability of the FIs 108 where a status of the FIs 108 cannot be altered. Also, as previously described, F in Equation (6) indicates the objective function for minimizing the total costs combining equipment and outage cost, which we are trying to minimize in our optimization problem. x^{→} denotes the vector of decision variables, which are X^{RCS}_{f,j}, X^{MS}_{f,j} and X^{FI}_{f,j}, subject to constraints (1)-(2) and (4)-(59).

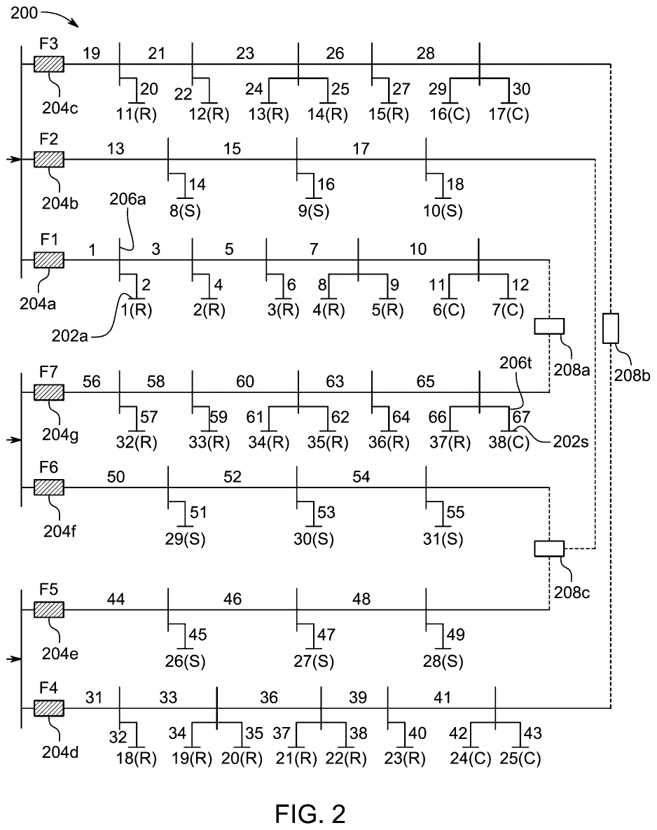

FIG. 2 illustrates a single-line diagram of a Roy Billington Test System (RBTS-Bus 4) 200, according to certain embodiments. In an embodiment, the RBTS-Bus 4 200 may be designed to test effectiveness of the fault isolation and restoration mechanisms, making a suitable environment for studying the optimization of the placement of the FIs 108 (as shown in FIG. 1A), the RCSs 110 (as shown in FIG. 1A), and the MSs 112 (as shown in FIG. 1A). In an embodiment, the RBTS-Bus 4 200 incorporates failure rates and the costs for different types of the devices such as, the FIs 108, the RCSs 110, and the MSs 112, which are essential for optimizing the placement of the devices.

The RBTS-Bus 4 200 may include load points 202a-202s (hereinafter referred to as the load points 202), where s is equal to 38. In an exemplary embodiment, the load points 202 may be residential (R) load points, commercial (C) load points and sensitive (S) load points. The RBTS-Bus 4 200 may further include feeders 204a-204g (hereinafter referred to as the feeders 204), where g is equal to 7. The RBTS-Bus 4 200 may also include overhead lines 206a-206t (hereinafter referred to as the overhead lines 206), where t is equal to 67. The RBTS-Bus 4 200 may also include three tie switches 208a-208c (hereinafter referred to as the three tie switches 208), and serves a customer base of 4,779. Further, a failure rate of the overhead lines 206 may be set at 0.065 faults per year per kilometer (f/yr.km), indicating a likelihood of the faults of the overhead lines 206. In addition, the FIs 108, RCSs 110, and MSs 112 may be assigned a capital cost of $1,000, $4,700, and $500, respectively, with annual maintenance costs calculated as 5% of the capital cost. These costs impact overall operational budget and planning. The study is based on a 15-year period with an annual load growth rate of 1.1%. Further, a discount rate of 5% is applied to account for a time value of the costs over a study period. Moreover, a remote-controlled restoration time is set at 5 minutes, while a fault section repair takes an average of 120 minutes.

Also, a field crew patrol speed is 10 km/h, with a preparation time of 25 minutes. Reliability considerations such as, the malfunction probabilities for the FIs 108, the RCSs 110, and the MSs 112 may be set at 0.01, 0.05, and 0.02 respectively. The isolation capability failure probability for the RCS 110 communication may be 0.015. These probabilities are crucial for modelling the resilience and fault isolation efficiency of the network 100. The RBTS-Bus 4 200 setup provides a structured framework for analyzing outage impacts, cost assessments, and equipment efficiency in the fault isolation and the restoration in the network 100.

Table 1 presents a baseline comparison, representing the network 100 without the FIs 108 and the SSs such as, the RCSs 110 and the MSs 112 in the network 100. Purpose of this case 1 is to underscore importance of placing the FIs 108, the RCSs 110 and the MSs 112 in the network 100. Results of the case 1 are presented in Table 1 as below.

TABLE 1
Total Costs and SAIDI index: Case 1

| | | | | | Reliability |
|---|---|---|---|---|---|
| Costs (US k$) | | | | | index |
| FI | MS | RCS | Outage | Total | SAIDI |
| 108 | 112 | 110 | Costs | Costs | (hr/yr.cust) |
| 0 | 0 | 0 | 994.74 | 994.74 | 1.024 |

where all costs associated with the FI 108, the RCS 110, and the MS 112 are 0 as these devices are absent in the network 100. The outage costs are the costs associated with customer outages due to absence of the fault isolation and the restoration capabilities, amounting to $994.74. Since no additional components are used, the total cost is $994.74. System average interruption duration index (SAIDI) measures average outage duration per customer per year, which is 1.024 hours in this case.

Further, Table 2 illustrates the optimal placement locations for the RCSs 110 and the MSs 112 on each feeder 204, by considering with malfunction and without malfunction. An effect of the malfunction on the placement of the RCSs 110 and the MSs 112 may be observed in Table 2 as below.

TABLE 2
Optimal device locations: Case 2

| | MS 112 locations | | RCS 110 locations | |
|---|---|---|---|---|
| Feeder | Without | With | Without | With |
| 204 | Malfunction | Malfunction | Malfunction | malfunction |
| 1 | 3E, 5B, 7E | 5E | 10E | 10E |
| 2 | 13E, 15B, 17B, | 13E, 15B | 15E | 15E, 17B |
| | 17E | | | |
| 3 | 21E, 23E, 26B | 23E | 28E | 28E |
| 4 | 33E, 39B | 33E | 36B, 41E | 36E, 41E |
| 5 | 44B, 46B, 48B, | 44E, 48B | 46E | 46E |
| | 48E | | | |
| 6 | 50E, 52B, 54B, | 50E, 52B, | 52E | 52E, 54E |
| | 54E | 54B | | |
| 7 | 58B, 60E, 63B | 60E | 65E | 65E |
| Total | 23 | 11 | 8 | 10 |

where B denotes a beginning of the feeder 204 and E denotes an end of the feeder 204.

Table 3 represents findings, including the optimal location of the RCSs 110 and the MSs 112, total expenses, a common reliability index, and the SAIDI for the case 2.

TABLE 3
Total costs and SAIDI index: Case 2

| | | | | | Reliability |
|---|---|---|---|---|---|
| | Costs (US k$) | | | | index |
| | MS | RCS | Outage | Total | SAIDI |
| Scenario | 112 | 110 | Costs | Costs | (hr/yr.cust) |
| Without | 16.81 | 54.98 | 190.55 | 262.34 | 0.4272 |
| malfunction | | | | | |
| With | 8.04 | 68.72 | 222.51 | 299.27 | 0.4723 |
| Malfunction | | | | | |

Table 3 shows the cost of installing the MS 112 and the RCS 110 devices. Costs are lower when the malfunction is considered due to reduced device count. Further, the outage costs are lower without the malfunction (i.e. $190.55) but increase to $222.51 with the malfunction. Also, the total cost of the MS 112, the RCS 110, and the outage cost is $262.34 without the malfunction and increase to $299.27 with the malfunction. The SAIDI is lower without the malfunction (i.e. 0.4272) and increase to 0.4723 when the malfunction is factored in.

Table 4 represents details of the placement of the MSs 112, the RCSs 110, and the FIs 108 in case 3, where each column displays the optimal locations of the MS 112, the RCS 110 and the FI 108 devices on each feeder 204, with and without malfunction.

TABLE 4
Optimal device locations: Case 3

| | MS 112 locations | | RCS 110 locations | | FI 108 locations | |
|---|---|---|---|---|---|---|
| | Without | With | Without | With | Without | With |
| Feeder | Mal- | Mal- | Mal- | Mal- | Mal- | Mal- |
| 204 | function | function | function | function | function | function |
| 1 | 3E, 5B, 7E | 5E | 10E | 10E | 5E | 5E |
| 2 | 13E, 15B, | 13E, 15B | 15E | 15E, 17B | | |
| | 17B, 17E | | | | | |
| 3 | 21E, 23E, | 23E | 28E | 28E | 23E | 23E |
| | 26B | | | | | |
| 4 | 33E, 36B, | 36E | 41E | 41E | 36B | 36B |
| | 39B | | | | | |
| 5 | 44B, 46B, | 44E, 48B | 46E | 46E | | |
| | 48B, 48E | | | | | |
| 6 | 50E, 52B, | 50E, 52B, | 52E | 52E, 54E | | |
| | 54B, 54E | 54B | | | | |
| 7 | 58B, 60E, | 60E | 65E | 65E | 60E | 60E |
| | 63B | | | | | |
| Total | 24 | 11 | 7 | 9 | 4 | 4 |

Similar to the case 2, the malfunctions reduce the number of MS 112 placements (from 24 to 11) and increase reliance on the RCSs 110. The FIs 108 are strategically placed to assist in the fault detection and isolation.

Further, Table 5 represents the total costs and the SAIDI for the case 3, which combines the MS 112, the RCS 110 and the FI 108 placements.

TABLE 5
Total costs and SAIDI index: Case 3

| | | | | | | Reliability |
|---|---|---|---|---|---|---|
| | Costs (US k$) | | | | | index |
| | MS | RCS | FI | Outage | Total | SAIDI |
| Scenario | 112 | 110 | 108 | Costs | Costs | (hr/yr.cust) |
| Without | 17.55 | 48.10 | 5.85 | 183.86 | 255.36 | 0.3841 |
| malfunction | | | | | | |
| With | 8.04 | 61.85 | 5.85 | 219.44 | 295.18 | 0.4541 |
| Malfunction | | | | | | |

Table 5 shows the cost of installing the MS 112, RCS 110 and the FI 108 devices. FI 108 cost is constant at $5.85 as the placement of the FI 108 remains unchanged. Further, the outage costs are lower without the malfunction (i.e. $183.86) but increase to $219.44 with the malfunction. Also, the total cost of the MS 112, the RCS 110, the FI 108 and the outage cost is $255.36 without the malfunction and increase to $295.18 with the malfunction. The SAIDI is lower without the malfunction (i.e. 0.3841) and increase to 0.4541 when the malfunction is factored in.

Table 6 represents the costs of the system 114 including the MS 112 cost, the RCS 110 cost, the FI 108 cost, the outage cost, the SAIDI and computation times across different configuration (i.e. the case 2 and the case 3), with the malfunction and without the malfunction.

TABLE 6
System 114 costs and reliability index, SAIDI in different cases

| | Case 2 | | Case 3 | |
|---|---|---|---|---|
| | Without | With | Without | With |
| | malfunc- | malfunc- | malfunc- | malfunc- |
| | tion | tion | tion | tion |
| MS 112 | 16.81 | 5.12 | 17.55 | 5.12 |
| RCS 110 | 54.98 | 48.1 | 48.10 | 48.10 |
| FI 108 | — | — | 5.85 | 5.85 |
| Outage Cost | 190.55 | 251.49 | 183.86 | 239.42 |
| SAIDI | 0.4272 | 0.4723 | 0.3841 | 0.4541 |
| Computation | 24.64 | 43.14 | 49.43 | 99.33 |
| time | | | | |

From Table 6, it is observed that the case 2 only involves the placement of the MS 112 and the RCS 110, while the case 3 involves the placement of the MS 112, the RCS 110 and the FI 108 which results in a more optimal fault management setup as compared to the case 2. Also, both the case 2 and the case 3 shows lower outage costs and SAIDI values without the malfunction. This indicates that the devices such as, the MS 112, the RCS 110 and the FI 108 are effectively reducing customer interruptions and associated costs. However, when the malfunctions are introduced, an effectiveness of the system 114 declines. Malfunctions lead to the increased SAIDI and the outage cost.

For example, in the case 2, only the MS 112 and the RCS 110 malfunctions result in a 16.77% increase in the outage costs, as fewer MSs 112 and RCSs 110 are optimally placed due to malfunction considerations (i.e. reducing the MSs 112 and the RCSs 110 from 31 to 21). In the case 3, despite a joint placement of the MS 112, the RCS 110 and the FI 108, device numbers are optimized from 35 to 24, increasing the outage cost by 19.35% under malfunction conditions, indicating that the malfunctions still impact overall reliability despite the additional FIs 108. In particular, the malfunctions affect the placement of the MS 112 rather than the RCS 110 and the FIs 108, suggesting that the MSs 112 are more vulnerable to the malfunction. To mitigate the MS 112 malfunction, a number of RCS 110 placements increases during the malfunction conditions. Thus, the computation time required for optimization in each case rises significantly under the malfunction scenarios. For instance, in the case 2, the computation time increases from 24.64 minutes without the malfunction to 43.14 minutes with the malfunction. In the case 3, the computation time increases from 49.43 minutes without the malfunction to 99.33 minutes with the malfunction.

In an exemplary embodiment, a test system such as, the RBTS-BUS 4 200 is considered to illustrate the impact of the device malfunctions on the computation time. The RBTS-BUS 4 200 includes 51 locations available for the placement of the devices such as, the MS 112, RCS 110 and the FI 108. In the case 2, where only the MS 112 and the RCS 110 placements are considered, 102 binary variables are used to represent potential placement options. In the case 3, with the joint placement of the MS 112, the RCS 110, and the FI 108, the number of binary variables rises to 153, reflecting additional complexity introduced by the FIs 108.

When the malfunctions are considered, computational complexity further increases due to additional inequality constraints required to represent the malfunction probabilities and associated interruption costs. These constraints expand a search space, nearly doubling the computation time in the malfunction scenarios, as reflected in Table 6.

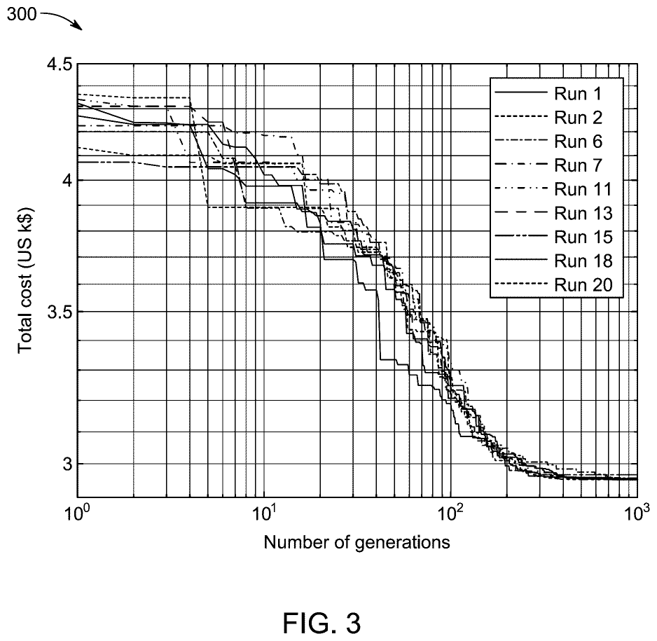

FIG. 3 illustrates a graphical representation 300 of multiple runs of the BSA, according to certain embodiments. The BSA may be executed independently 21 times to assess consistency and robustness of the BSA. Each run consistently converges to a near-optimal solution of 295.18 thousand USD (US k$), regardless of its starting point. This result highlights a reliability and a stability of the BSA in finding a solution close to a minimum cost each time, demonstrating a the robustness of the BSA in achieving the optimal placement of the devices (i.e. the MS 112, the RCS 110, and the FIs 108) for network 100 reliability and cost-effectiveness.

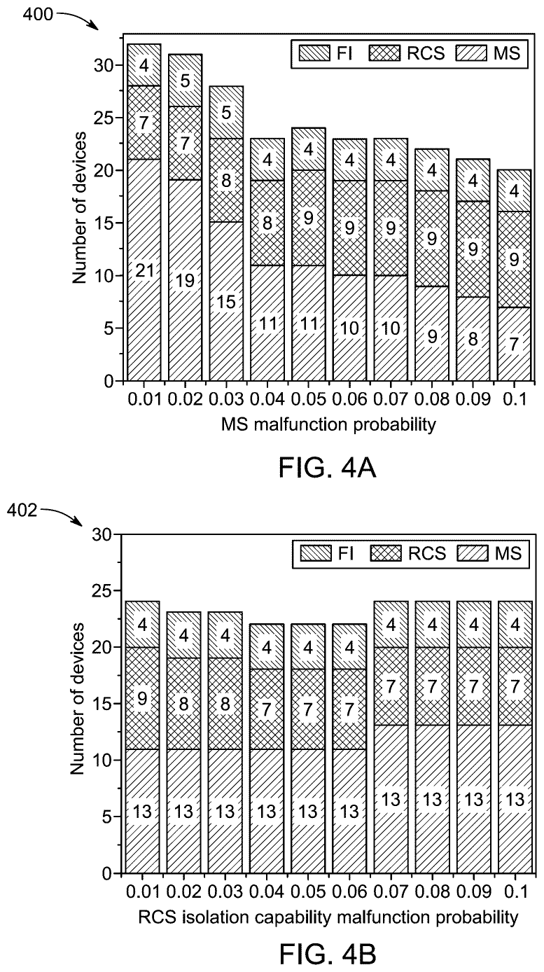

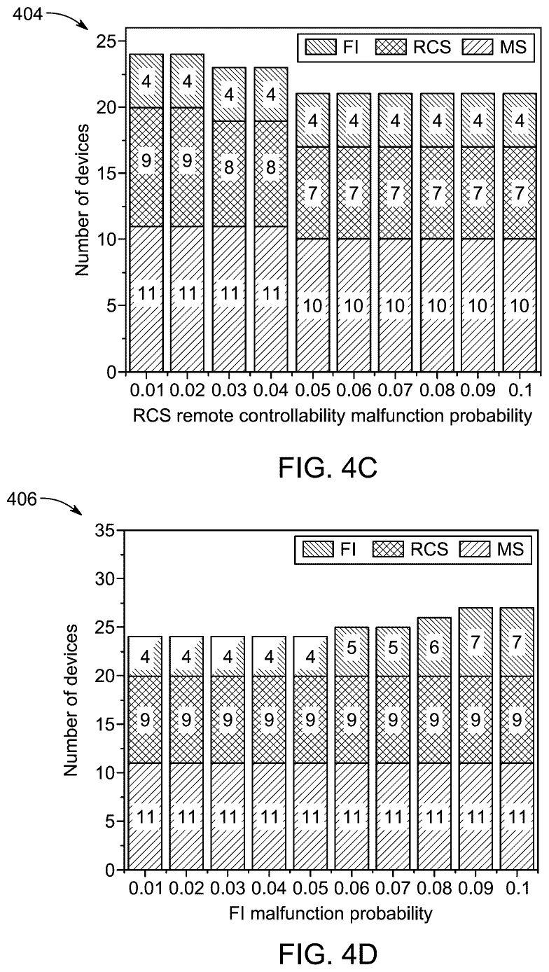

FIG. 4A illustrates a graphical representation 400 of the MS 112 placement with respect to the malfunction probability, according to certain embodiments. Referring to FIG. 4A, X-axis represents the malfunction probability of the MS 112 devices that is varied from 0.01 to 0.1 and Y-axis represents a number of the devices. As the malfunction probability of the MS 112 increases, a number of MS 112 devices decreases which illustrates that higher malfunction probabilities reduce an effectiveness of the MS 112 devices in manual restoration tasks. Consequently, fewer MS 112 devices are deployed or maintained as their reliability decreases. Further, to compensate for the reduction in the MS 112 devices, the number of RCS 110 devices increases as the MS 112 malfunction probability goes up. This suggests a compensatory mechanism within the system 114 as the MS 112 devices become less effective, the system 114 relies more on the RCS 110 devices to maintain overall functionality and resilience. Further, the FI 108 devices remain almost constant in number across all levels of the MS 112 malfunction probability. This stability indicates that the FI 108 devices are not directly impacted by changes in MS 112 reliability, or a role of the FS 108 in the system 114 does not require adjustment based on the MS 112 malfunction probability.

FIG. 4B illustrates a graphical representation 402 of the RCS 110 isolation capability with respect to the malfunction probability, according to certain embodiments. X-axis represents the malfunction probability of the RCS 110 isolation capability, which is varied from 0.01 to 0.1 and Y-axis represents the number of devices. Unlike MS 112 devices, the number of RCS devices 110 remains relatively stable, showing only a small decrease from 9 to 7 devices as the malfunction probability increases. In other words, despite of the RCS 110 malfunctions affecting automatic restoration, the system 114 continues to maintain a relatively high count of the RCS 110 devices.

This is likely because the RCS 110 devices still perform essential fault detection and isolation functions that other devices cannot replace. Further, as the malfunction probability of the RCS 110 increases, the number of MS 112 devices slightly increases from 11 to 13. This suggests that the system 114 compensates for reduced RCS 110 reliability by deploying more MS 112 devices, potentially to provide additional manual restoration support. The number of FI 108 devices remains constant at 4 across all levels of the RCS 110 malfunction probability. This consistency indicates that the FI 108 devices are not affected by changes in the RCS 110 reliability, as they may have a fixed role focused on the fault indication rather than the restoration.

FIG. 4C illustrates a graphical representation 404 of RCS 110 remote controllability malfunction probability, according to certain embodiments. X-axis represents the malfunction probability of the RCS 110 remote controllability, ranging from 0.01 to 0.1 and Y-axis represents the number of devices. As this probability increases, it allows observation of how the system 114 configuration responds when the remote control capability of the RCS 110 devices becomes less reliable. The number of RCS 110 devices shows a minor decrease from 9 to 7 as the malfunction probability increases. This slight reduction reflects that, even if the RCS 110 devices lose remote controllability, they can still be used manually for isolation purposes. The count of the MS 112 devices remains mostly stable, only decreasing from 11 to 10 as the malfunction probability increases. Unlike the case of the RCS 110 isolation malfunctions, the system 114 does not need to increase the number of MS 112 devices because the RCS 110 can still perform manual isolation despite losing remote controllability.

The number of FI 108 devices remains constant at 4 across all malfunction probabilities, as the FI 108 devices are primarily used for the fault indication and do not play a role in restoring the customers. This stability indicates that the FIs 108 are unaffected by the change in the RCS 110 remote controllability with respect to the malfunction probability, according to certain embodiments.

FIG. 4D illustrates a graphical representation 406 of the FI 108 placement with respect to the malfunction probability, according to certain embodiments. X-axis represents the malfunction probability of the FI 108 devices, ranging from 0.01 to 0.1 and Y-axis represents the number of devices. As the FI 108 malfunction probability increases, the system 114 likely increases the number of FIs 108 to maintain adequate fault detection. This adaptation ensures that even if some FIs 108 fail, enough functional devices remain in the system 114 to continue performing the fault indication. Since the RCS 110 devices are more expensive, the system 114 avoids relying on the RCS 110 devices to fully compensate for the FI 108 malfunctions. Instead, the system 114 simply increases the FI 108 count to maintain reliability cost-effectively.

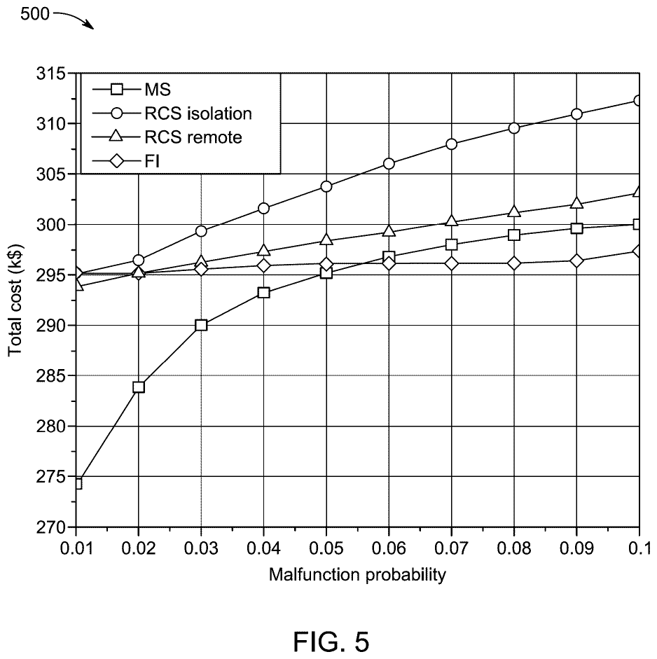

FIG. 5 illustrates a graph 500 representing a relationship between the total costs and the malfunction probabilities, according to certain embodiments. The horizontal axis represents the malfunction probabilities and the vertical axis represents the total costs associated with the malfunction probabilities.

The graph 500 illustrates that as the malfunction probability increases, the total costs also rise due to reduced effectiveness of the MS 112 and the RCS 110, leading to fewer placements of the MS 112 and the RCS 110, higher outages and increased the total cost. Referring to FIG. 4B, a higher cost is observed when the RCS 110 experiences the isolation malfunctions, as the isolation malfunctions affect the reliability of the system 114. However, in case of the FI 108 malfunctions (as shown in FIG. 4D), although the number of FIs 108 increases to maintain the detection capabilities, the total cost does not rise as compared to the MS 112 and the RCS 110 malfunctions.

Table 7 represents a performance of the system 114 that is evaluated on a real distribution network 100 in Baghdad, Iraq, which consists of 49 buses, five tie-lines, and six laterals. The simulation is conducted for three distinct scenarios such as, for the case 1, the case 2, and case 3, similar to the test system 200, with the results for each scenario shown in Table 7.

TABLE 7
Results of the real network 100

| | | Number | | | System 114 costs | | |
|---|---|---|---|---|---|---|---|
| | | of devices | | | (US k$) | | |
| | | MS | RCS | FI | Equipment | Outage | Total |
| Cases | | 112 | 110 | 108 | costs | costs | costs |
| Case 1 | | 0 | 0 | 0 | 0 | 4149.7 | 4149.7 |
| Case 2 | Without | 43 | 14 | | 127.65 | 387.7 | 515.63 |
| | Malfunction | | | | | | |
| | With | 13 | 17 | | 126.33 | 524.08 | 650.41 |
| | Malfunction | | | | | | |
| Case 3 | Without | 42 | 15 | 6 | 142.56 | 362.78 | 505.32 |
| | Malfunction | | | | | | |
| | With | 13 | 17 | 6 | 135.10 | 497.89 | 632.99 |
| | Malfunction | | | | | | |

Table 7 presents data for the case 1, the case 2, and the case 3 with the malfunction and without the malfunction, including the number of devices, the equipment costs, the outage costs, and the total costs. The case 1 shows the system 114 without any devices, so there are no equipment costs or the outage costs.

Further, an analysis of the case 2 may be divided into two parts: without the malfunctions, there are 43 MS 112, 14 RCS 110 and no FI 108, resulting in the equipment costs of 127.65 k$, the outage costs of 387.7 k$, and the total costs of 515.63 k$. When the malfunction is accounted for, the number of MS 112 reduces significantly to 13, while the number of RCS 110 increases to 17. The equipment costs slightly decrease, but the outage costs increase significantly, leading to higher total costs of 650.41 k$.

Similar to the case 2, the case 3 considers the joint placement of the FIs 108, the RCS 110, and the MS 112, where without malfunctions, the system 114 has 42 MS 112, 15 RCS 110, and 6 FIs 108, with the equipment costs of 142.56 k$, the outage costs of 362.78 k$, and the total costs of 505.32 k$.

In the case 3, when the malfunctions are considered, the number of MS 112 decreases to 13, while the number of RCS 110 remains at 17 and the number of FIs 108 remains unchanged. The total costs increase to 632.99 k$ due to a rise in the outage costs.

An analysis of Table 7 shows that when the malfunction is taken into account, quantity of FIs 108 and the SSs decreases as their benefits are overestimated in absence of the malfunction. Although the number of MS 112 reduces significantly, the number of RCS 110 increases like the test system 200 and the FI 108 remains relatively unchanged to mitigate the impact of malfunctions in the MSs 112. Consequently, optimal solution for the joint placement of FIs 108 and the SSs aligns with the outcomes of the test system 200. However, it is noteworthy that the overall cost has risen by 25.27%, attributable to the reduction in the number of SSs and FIs 108 along with an increase in the outage cost.

Table 8 represents a comparison between the system 114 and conventional approaches for the device placement in the network 100. The system 114 is compared with the conventional approaches and is summarized in Table 8. It is observed from Table 8 that the system 114 is efficient in comparison to the conventional approaches. In an aspect, many existing studies focus mainly on minimizing the equipment cost and the outage cost. Most of the existing studies has concentrated only on the SS placement, without considering benefits of combining it with other devices like the FIs 108. A few studies have explored the joint placement of the SS and the FI 108; however, none have extended this joint approach to consider the device malfunction probabilities. The system 114, by contrast, is a first to jointly place the FI 108 and the SS while accounting for potential malfunctions in the network 100. In an aspect, few existing studies have factored in the device malfunctions. Some studies examined SS malfunctions alone, while others considered the RCS 110 malfunctions. In contrast, the system 114 uniquely incorporates the malfunction probabilities for both the FI 108 and the SS devices, providing a more realistic and resilient model ofethe network 100.

In an aspect, the current studies often assume a uniform fault location time for all lines, which is unrealistic. The fault location time typically varies based on a line length, a field crew patrolling time, and the positioning of the FI 108, the RCS 110, and the MS 112 in the network 100. Also, many previous studies may rely on MJLP or MIP, which need specific problem formatting and third-party solvers, potentially adding complexity and dependency. However, the system 114 uses the BSA, which requires no specific formatting or the third-party solvers. Although the BSA may take longer to solve than the MJLP, it is well-suited for a planning nature of a problem, prioritizing accuracy and adaptability.

TABLE 8
Comparative analysis among the system 114 and the conventional approaches.

| | | A. C. | M. | B. | A. | M. | A. | J. | N. | |
|---|---|---|---|---|---|---|---|---|---|---|
| | | Gomes | Jooshaki | Li | Safdarian | Farajollahi | Shahbazian | Forcan | Gholizadeh | System |
| Study | | et al. | et al. | et al. | et al. | et al. | et al. | et al. | et al. | 114 |
| Objective | EC | ✓ | ✓ | ✓ | ✓ | ✓ | ✓ | ✓ | ✓ | ✓ |
| | OC | X | X | ✓ | ✓ | ✓ | ✓ | ✓ | ✓ | ✓ |
| | EENS | ✓ | ✓ | X | X | X | X | X | X | X |
| | SAIDI | X | ✓ | X | X | X | ✓ | X | X | X |
| Method | MILP | ✓ | ✓ | ✓ | X | X | ✓ | ✓ | ✓ | X |
| | MIP | X | X | X | ✓ | ✓ | X | X | X | X |
| | MINL | X | X | X | X | X | X | X | ✓ | X |
| | P | | | | | | | | | |
| | Heuristics | ✓ | X | X | X | X | X | X | X | X |
| | Meta- | X | X | X | X | X | X | X | X | ✓ |
| | heuristic | | | | | | | | | |
| Protection | RCS | ✓ | ✓ | ✓ | ✓ | ✓ | ✓ | ✓ | ✓ | ✓ |
| Device | 110 | | | | | | | | | |
| | MS | ✓ | ✓ | ✓ | ✓ | ✓ | ✓ | X | ✓ | ✓ |
| | 112 | | | | | | | | | |
| | FI 108 | X | X | ✓ | ✓ | X | X | X | X | ✓ |
| | Tie | X | ✓ | X | X | X | X | X | X | X |
| | Lines | | | | | | | | | |
| | 120 | | | | | | | | | |
| Malfunction | RCS | X | X | X | X | ✓ | X | X | X | ✓ |
| | 110 | | | | | | | | | |
| | MS | X | X | X | X | ✓ | X | X | X | ✓ |
| | 112 | | | | | | | | | |
| | FI 108 | X | X | X | X | X | X | X | X | ✓ |

| | | | | | | | | | |
|---|---|---|---|---|---|---|---|---|---|
| Specific | ✓ | ✓ | ✓ | ✓ | ✓ | ✓ | ✓ | ✓ | X |
| Formatting | | | | | | | | | |
| Third Party Solver | ✓ | ✓ | ✓ | ✓ | ✓ | ✓ | ✓ | ✓ | X |
| Load Growth | ✓ | ✓ | X | ✓ | ✓ | X | ✓ | ✓ | ✓ |
| Type of | X | ✓ | ✓ | ✓ | ✓ | ✓ | ✓ | ✓ | ✓ |
| Customers | | | | | | | | | |

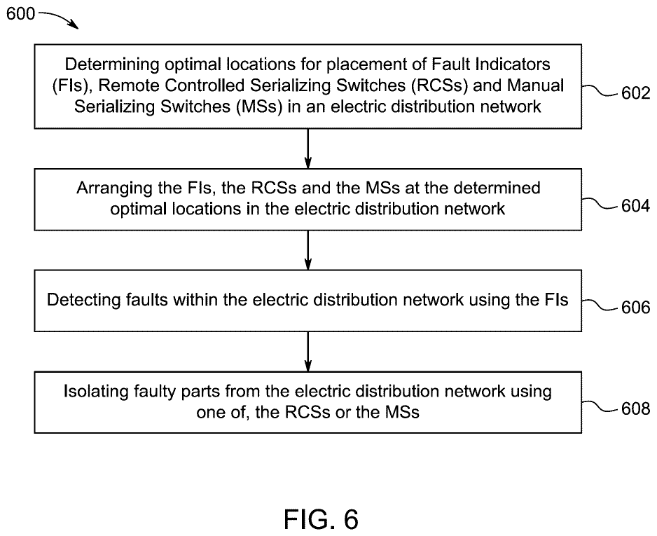

FIG. 6 illustrates a flowchart of a method 600 for performing the fault management in the network 100, according to certain embodiments.

At step 602, the method 600 may include determining the optimal locations for the placement of the FIs 108, the RCSs 110, and the MSs 112 in the network 100 by solving the objective function using the population-based meta-heuristic algorithm. While solving the objective function, the network 100 is structured as the radial network. The objective function is a sum of the equipment factor associated with the FIs 108, the RCSs 110, and the MSs 112, and the outage factor associated with the service interruptions of the network 100, to be minimized. In an aspect, the objective function includes a first term, a second term and a fault locating time. The first term represents the outage factor calculated based on the malfunction probability of the FIs 108, the RCSs 110, and the MSs 112. The second term represents the equipment factor associated with the FIs 108, the RCSs 110, and the MSs 112. The fault locating time varies based on the line length, the field crew patrolling, and the locations of the FIs 108, the RCSs 110, and the MSs 112 within the network 100.

The first term (i.e., the outage factor) is a weighted sum of (1) the outage factor that is calculated by assuming that there is no malfunction in the FIs 108, the RCSs 110, and the MSs 112, (2) the outage factor that is calculated based on the malfunction probability of the MSs 112 where a status of the MSs 112 cannot be altered, (3) the outage factor that is calculated based on the malfunction probability of the isolation capability of the RCSs 110 where a status of the RCSs 110 cannot be altered, (4) the outage factor that is calculated based on the malfunction probability of the remote communication capability of the RCSs 110 where the status of the RCSs 110 can be altered manually but not remotely, and (5) the outage factor that is calculated based on the malfunction probability of the FIs 108 where a status of the FIs 108 cannot be altered.

The second term includes a sum of the installation factor associated with the FIs 108, the RCSs 110, and the MSs 112, and the maintenance factor associated with the FIs 108, the RCSs 110, and the MSs 112. In an aspect, the installation factor is associated with the communication devices required by the FIs 108, the RCSs 110, and the MSs 112 and the maintenance factor is calculated using the discount factor that is determined based on the investment factor and the time factor associated with the FIs 108, the RCSs 110, and the MSs 112. In an aspect, the total number of the RCSs 110 and the MSs 112 arranged at each location in the network 100 is not more than 1. In another aspect, the total number of the RCSs 110 and the FIs 108 arranged at each position within the network 100 is not more than 1.

At step 604, the method 600 includes arranging the FIs 108, the RCSs 110 and the MSs 112 at the determined optimal locations in the network 100.

At step 606, the method 600 includes detecting the faults within the network 100 and providing the information on the detected faults, using the FIs 108 arranged in the network 100.

At step 608, the method 600 includes isolating the faulty parts from the network 100 and ensuring the power supply to the unfaulty parts. In an aspect, isolating the faulty parts from the network 100 may involve using the RCSs 110 arranged in the network 100. In another aspect, isolating the faulty parts from the network 100 may involve using the MSs 112 arranged in the network 100.

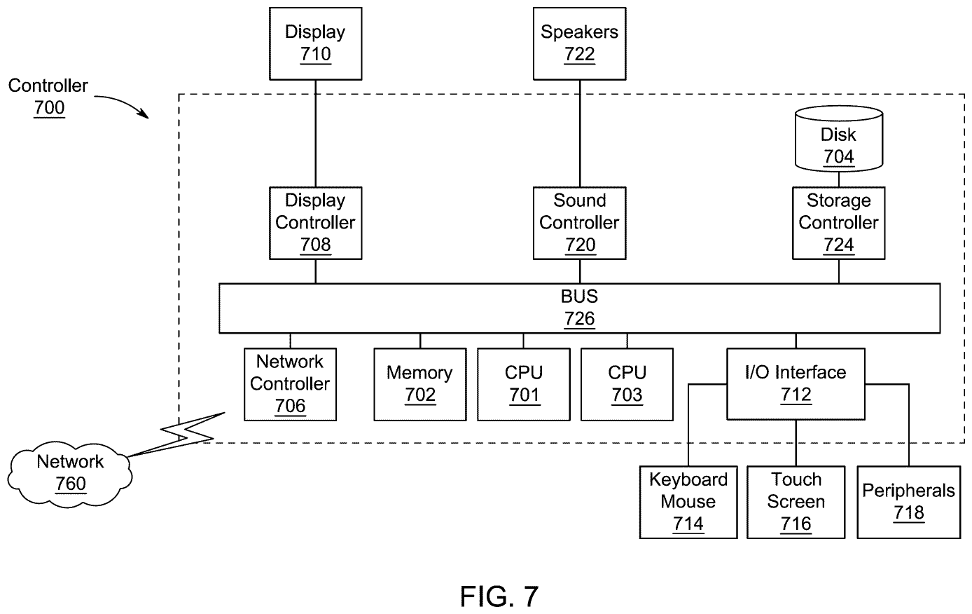

Next, further details of the hardware description of the computing environment of according to exemplary embodiments is described with reference to FIG. 7. In FIG. 7, a controller 700 is described is representative of the system in which the controller is a computing device which includes a CPU 701 which performs the processes described above/below. The process data and instructions may be stored in memory 702. These processes and instructions may also be stored on a storage medium disk 704 such as a hard drive (HDD) or portable storage medium or may be stored remotely.

Further, the claims are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the computing device communicates, such as a server or computer.

Further, the claims may be provided as a utility application, background daemon, or component of an operating system, or combination thereof, executing in conjunction with CPU 701, 703 and an operating system such as Microsoft Windows 7, Microsoft Windows 10, UNIX, Solaris, LINUX, Apple MAC-OS and other systems known to those skilled in the art.

The hardware elements in order to achieve the computing device may be realized by various circuitry elements, known to those skilled in the art. For example, CPU 701 or CPU 703 may be a Xenon or Core processor from Intel of America or an Opteron processor from AMD of America, or may be other processor types that would be recognized by one of ordinary skill in the art. Alternatively, the CPU 701, 703 may be implemented on an FPGA, ASIC, PLD or using discrete logic circuits, as one of ordinary skill in the art would recognize. Further, CPU 701, 703 may be implemented as multiple processors cooperatively working in parallel to perform the instructions of the inventive processes described above.

The computing device in FIG. 7 also includes a network controller 706, such as an Intel Ethernet PRO network interface card from Intel Corporation of America, for interfacing with network 760. As can be appreciated, the network 760 can be a public network, such as the Internet, or a private network such as an LAN or WAN network, or any combination thereof and can also include PSTN or ISDN sub-networks. The network 760 can also be wired, such as an Ethernet network, or can be wireless such as a cellular network including EDGE, 3G and 4G wireless cellular systems. The wireless network can also be WiFi, Bluetooth, or any other wireless form of communication that is known.

The computing device further includes a display controller 708, such as a NVIDIA GeForce GTX or Quadro graphics adaptor from NVIDIA Corporation of America for interfacing with display 710, such as a Hewlett Packard HPL2445w LCD monitor. A general purpose I/O interface 712 interfaces with a keyboard and/or mouse 714 as well as a touch screen panel 716 on or separate from display 710. General purpose I/O interface also connects to a variety of peripherals 718 including printers and scanners, such as an OfficeJet or DeskJet from Hewlett Packard.

A sound controller 720 is also provided in the computing device such as Sound Blaster X-Fi Titanium from Creative, to interface with speakers/microphone 722 thereby providing sounds and/or music.

The general purpose storage controller 724 connects the storage medium disk 704 with communication bus 726, which may be an ISA, EISA, VESA, PCI, or similar, for interconnecting all of the components of the computing device. A description of the general features and functionality of the display 710, keyboard and/or mouse 714, as well as the display controller 708, storage controller 724, network controller 706, sound controller 720, and general purpose I/O interface 712 is omitted herein for brevity as these features are known.

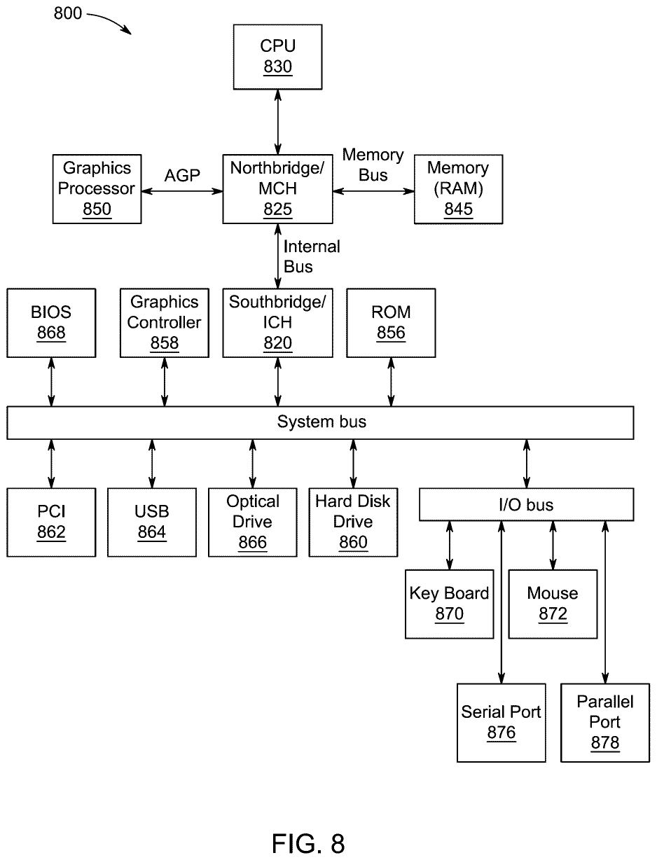

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset, as shown on FIG. 8.

FIG. 8 shows a schematic diagram of a data processing system, according to certain embodiments, for performing the functions of the exemplary embodiments. The data processing system is an example of a computer in which code or instructions implementing the processes of the illustrative embodiments may be located.

In FIG. 8, data processing system 800 employs a hub architecture including a north bridge and memory controller hub (NB/MCH) 825 and a south bridge and input/output (I/O) controller hub (SB/ICH) 820. The central processing unit (CPU) 830 is connected to NB/MCH 825. The NB/MCH 825 also connects to the memory 845 via a memory bus, and connects to the graphics processor 850 via an accelerated graphics port (AGP). The NB/MCH 825 also connects to the SB/ICH 820 via an internal bus (e.g., a unified media interface or a direct media interface). The CPU Processing unit 830 may contain one or more processors and even may be implemented using one or more heterogeneous processor systems.

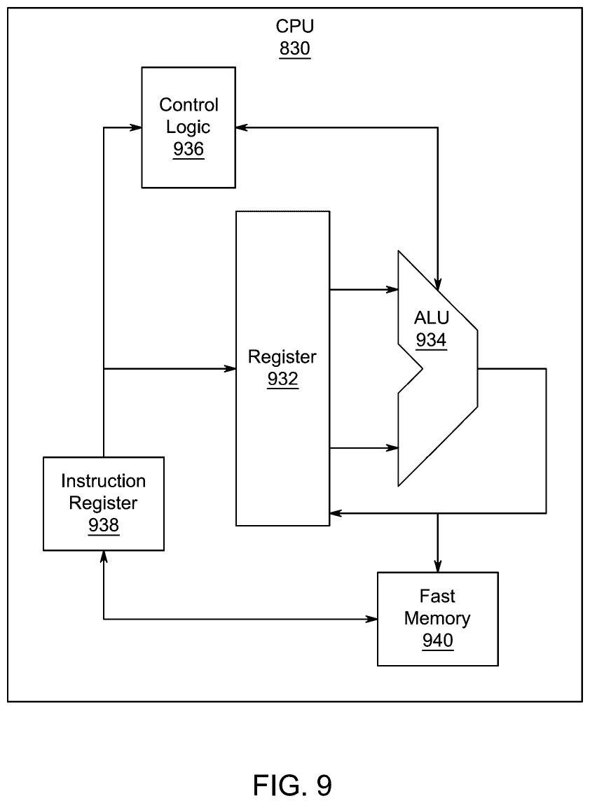

For example, FIG. 9 shows one implementation of CPU 830. In one implementation, the instruction register 938 retrieves instructions from the fast memory 940. At least part of these instructions are fetched from the instruction register 938 by the control logic 936 and interpreted according to the instruction set architecture of the CPU 830. Part of the instructions can also be directed to the register 932. In one implementation the instructions are decoded according to a hardwired method, and in another implementation the instructions are decoded according to a microprogram that translates instructions into sets of CPU configuration signals that are applied sequentially over multiple clock pulses. After fetching and decoding the instructions, the instructions are executed using the arithmetic logic unit (ALU) 934 that loads values from the register 932 and performs logical and mathematical operations on the loaded values according to the instructions. The results from these operations can be feedback into the register and/or stored in the fast memory 940. According to certain implementations, the instruction set architecture of the CPU 830 can use a reduced instruction set architecture, a complex instruction set architecture, a vector processor architecture, a very large instruction word architecture. Furthermore, the CPU 830 can be based on the Von Neuman model or the Harvard model. The CPU 830 can be a digital signal processor, an FPGA, an ASIC, a PLA, a PLD, or a CPLD. Further, the CPU 830 can be an x86 processor by Intel or by AMD; an ARM processor, a Power architecture processor by, e.g., IBM; a SPARC architecture processor by Sun Microsystems or by Oracle; or other known CPU architecture.

Referring again to FIG. 8, the data processing system 800 can include that the SB/ICH 820 is coupled through a system bus to an I/O Bus, a read only memory (ROM) 856, universal serial bus (USB) port 864, a flash binary input/output system (BIOS) 868, and a graphics controller 858. PCI/PCIe devices can also be coupled to SB/ICH 888 through a PCI bus 862.

The PCI devices may include, for example, Ethernet adapters, add-in cards, and PC cards for notebook computers. The Hard disk drive 860 and CD-ROM 866 can use, for example, an integrated drive electronics (IDE) or serial advanced technology attachment (SATA) interface. In one implementation the I/O bus can include a super I/O (SIO) device.

Further, the hard disk drive (HDD) 860 and optical drive 866 can also be coupled to the SB/ICH 820 through a system bus. In one implementation, a keyboard 870, a mouse 872, a parallel port 878, and a serial port 876 can be connected to the system bus through the I/O bus. Other peripherals and devices that can be connected to the SB/ICH 820 using a mass storage controller such as SATA or PATA, an Ethernet port, an ISA bus, a LPC bridge, SMBus, a DMA controller, and an Audio Codec.

Moreover, the present disclosure is not limited to the specific circuit elements described herein, nor is the present disclosure limited to the specific sizing and classification of these elements. For example, the skilled artisan will appreciate that the circuitry described herein may be adapted based on changes on battery sizing and chemistry, or based on the requirements of the intended back-up load to be powered.

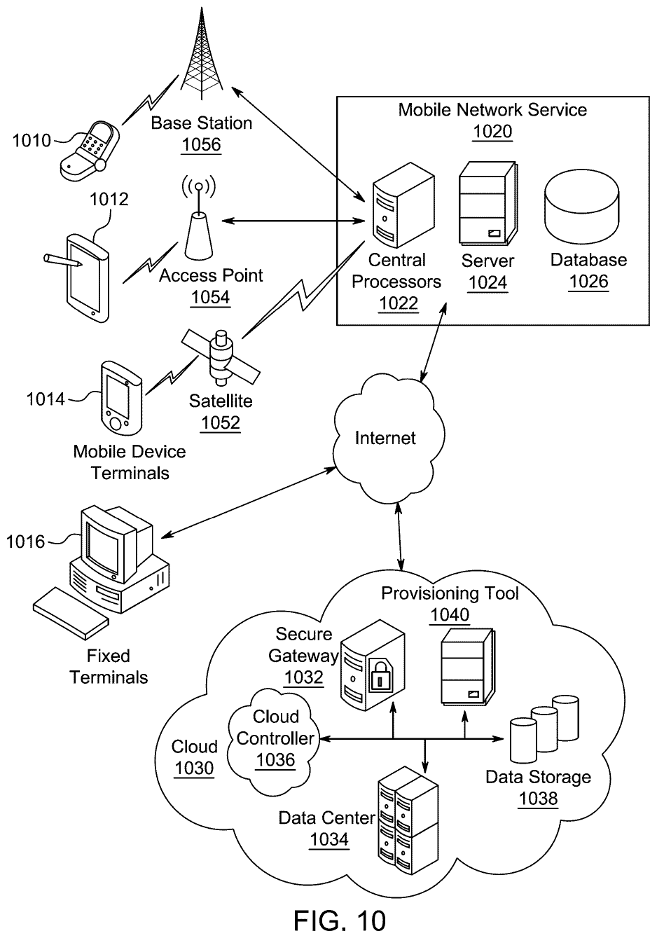

The functions and features described herein may also be executed by various distributed components of a system. For example, one or more processors may execute these system functions, wherein the processors are distributed across multiple components communicating in a network. The distributed components may include one or more client and server machines, which may share processing, as shown by FIG. 10, in addition to various human interface and communication devices (e.g., display monitors, smart phones, tablets, personal digital assistants (PDAs)). The network may be a private network, such as a LAN or WAN, or may be a public network, such as the Internet. Input to the system may be received via direct user input and received remotely either in real-time or as a batch process. Additionally, some implementations may be performed on modules or hardware not identical to those described. Accordingly, other implementations are within the scope of the disclosure.

The above-described hardware description is a non-limiting example of corresponding structure for performing the functionality described herein.

Numerous modifications and variations of the present disclosure are possible in light of the above teachings. It is therefore to be understood that the invention may be practiced otherwise than as specifically described herein.

1. A system for performing fault management in an electric distribution network, comprising:
a plurality of fault indicators (FIs),
a plurality of remote-controlled sectionalizing switches (RCSs), and
a plurality of manual sectionalizing switches (MSs) arranged in the electric distribution network,
wherein the plurality of FIs are configured to detect faults within the electric distribution network and provide information on the detected faults,
the plurality of RCSs and the plurality of MSs are configured to isolate faulty parts from the electric distribution network to ensure power supply to unfaulty parts,
the plurality of FIs, the plurality of RCSs, and the plurality of MSs are arranged at locations within the electric distribution network that are determined by solving an objective function, such that a sum of (1) an equipment factor associated with the plurality of FIs, the plurality of RCSs, and the plurality of MSs, and (2) an outage factor associated with service interruptions of the electric distribution network, to be minimized, and
the objective function includes a first term representing an outage factor calculated based on malfunction probability of the plurality of FIs, the plurality of RCSs, and the plurality of MSs.

2. The system of claim 1, wherein the first term includes a weighted sum of (1) an outage factor calculated assuming that there is no malfunction in the plurality of FIs, the plurality of RCSs, and the plurality of MSs, (2) an outage factor calculated based on malfunction probability of an MS where a status of an MS cannot be altered, (3) an outage factor calculated based on malfunction probability of a RCS where a status of a RCS cannot be altered, (4) an outage factor calculated based on malfunction probability of a remote communication capability of a RCS where a status of a RCS can be altered manually but not remotely, and (5) an outage factor calculated based on malfunction probability of an FT where a status of an FT cannot be altered.

3. The system of claim 1, wherein the objective function includes a second term representing the equipment factor associated with the plurality of FIs, the plurality of RCSs, and the plurality of MSs, and
the second term includes a sum of (1) an installation factor associated with the plurality of FIs, the plurality of RCSs, and the plurality of MSs, and (2) a maintenance factor associated with the plurality of FIs, the plurality of RCSs, and the plurality of MSs.

4. The system of claim 3, wherein the installation factor further includes an installation factor associated with communication devices required by the plurality of FIs, the plurality of RCSs, and the plurality of MSs, and
the maintenance factor is calculated using a discount factor, the discount factor being determined based on an investment factor and a time factor associated with the plurality of FIs, the plurality of RCSs, and the plurality of MSs.

5. The system of claim 1, wherein a population-based meta-heuristic algorithm is applied when solving the objective function, so as to determine the locations of the plurality of FIs, the plurality of RCSs, and the plurality of MSs within the electric distribution network.

6. The system of claim 5, wherein the population-based meta-heuristic algorithm applied when solving the objective function is a back-tracking search algorithm.

7. The system of claim 1, wherein when solving the objective function, the electric distribution network is structured as a radial network.

8. The system of claim 1, wherein the plurality of FIs, the plurality of RCSs, and the plurality of MSs are arranged at the locations within the electric distribution network that are determined by solving the objective function, such that a total number of RCSs and MSs arranged at each position within the electric distribution network is not more than 1.

9. The system of claim 1, wherein the plurality of FIs, the plurality of RCSs, and the plurality of MSs are arranged at the locations within the electric distribution network that are determined by solving the objective function, such that a total number of RCSs and FIs arranged at each position within the electric distribution network is not more than 1.

10. The system of claim 1, wherein the objective function includes a term representing a fault locating time, and the fault locating time varies based on line length, field crew patrolling, and the locations of the plurality of FIs, the plurality of RCSs, and the plurality of MSs within the electric distribution network.

11. A method for performing fault management in an electric distribution network, comprising:
detecting faults within the electric distribution network and providing information on the detected faults, using a plurality of fault indicators (FIs) arranged in the electric distribution network; and
isolating faulty parts from the electric distribution network and ensuring power supply to unfaulty parts, using a plurality of remote-controlled sectionalizing switches (RCSs) and a plurality of manual sectionalizing switches (MSs) arranged in the electric distribution network, wherein
the plurality of FIs, the plurality of RCSs, and the plurality of MSs are arranged at locations within the electric distribution network that are determined by solving an objective function, such that a sum of (1) an equipment factor associated with the plurality of FIs, the plurality of RCSs, and the plurality of MSs, and (2) an outage factor associated with service interruptions of the electric distribution network, to be minimized, and
the objective function includes a first term representing an outage factor calculated based on malfunction probability of the plurality of FIs, the plurality of RCSs, and the plurality of MSs.

12. The method of claim 11, wherein the first term includes a weighted sum of (1) an outage factor calculated assuming that there is no malfunction in the plurality of FIs, the plurality of RCSs, and the plurality of MSs, (2) an outage factor calculated based on malfunction probability of the plurality of MSs where a status of one or more of the plurality of MSs cannot be altered, (3) an outage factor calculated based on malfunction probability of an isolation capability of the plurality of RCSs where a status of one or more of the plurality of RCSs cannot be altered, (4) an outage factor calculated based on malfunction probability of a remote communication capability of the plurality of RCSs where a status of one or more of the plurality of RCSs can be altered manually but not remotely, and (5) an outage factor calculated based on malfunction probability of the plurality of FIs where a status of one or more the plurality of FIs cannot be altered.

13. The method of claim 11, wherein the objective function includes a second term representing the equipment factor associated with the plurality of FIs, the plurality of RCSs, and the plurality of MSs, and
the second term includes a sum of (1) an installation factor associated with the plurality of FIs, the plurality of RCSs, and the plurality of MSs, and (2) a maintenance factor associated with the plurality of FIs, the plurality of RCSs, and the plurality of MSs.

14. The method of claim 1, wherein the installation factor further includes an installation factor associated with communication devices required by the plurality of FIs and the plurality of RCSs, and
the maintenance factor is calculated using a discount factor, the discount factor being determined based on an investment factor and a time factor associated with the plurality of FIs, the plurality of RCSs, and the plurality of MSs.

15. The method of claim 1, wherein a population-based meta-heuristic algorithm is applied when solving the objective function, so as to determine the locations of the plurality of FIs, the plurality of RCSs, and the plurality of MSs within the electric distribution network.

16. The method of claim 15, wherein the population-based meta-heuristic algorithm applied when solving the objective function is a back-tracking search algorithm.

17. The method of claim 11, wherein when solving the objective function, the electric distribution network is structured as a radial network.

18. The method of claim 11, wherein the plurality of FIs, the plurality of RCSs, and the plurality of MSs are arranged at the locations within the electric distribution network that are determined by solving the objective function, such that a total number of RCSs and MSs arranged at each position within the electric distribution network is not more than 1.

19. The method of claim 11, wherein the plurality of FIs, the plurality of RCSs, and the plurality of MSs are arranged at the locations within the electric distribution network that are determined by solving the objective function, such that a total number of RCSs and FIs arranged at each position within the electric distribution network is not more than 1.

20. The method of claim 11, wherein the objective function includes a term representing a fault locating time, and the fault locating time varies based on a line length, field crew patrolling, and the locations of the plurality of FIs, the plurality of RCSs, and the plurality of MSs within the electric distribution network.
